(19) United States
(12) Patent Application Publication
(10) Pub. No.: US 2025/0113507 A1
(43) Pub. Date: Apr. 3, 2025

(54) ALUMINUM NITRIDE-BASED HIGH POWER DEVICES AND METHODS OF MAKING THE SAME

(71) Applicant: Georgia Tech Research Corporation, Atlanta, GA (US)

(72) Inventors: William Alan Doolittle, Atlanta, GA (US); Habib Ahmad, Atlanta, GA (US); Zachary P. Engel, Atlanta, GA (US); Christopher M. Matthews, Atlanta, GA (US); Keisuke Motoki, Atlanta, GA (US); Alex S. Weidenbach, Atlanta, GA (US)

(21) Appl. No.: 18/727,145

(22) PCT Filed: Jan. 11, 2023
(86) PCT No.: PCT/US2023/060469

§ 371 Date: Jul. 8, 2024

Related U.S. Application Data
(60) Provisional application No. 63/298,387, filed on Jan. 11, 2022.
(60) Provisional application No. 63/298,424, filed on Jan. 11, 2022.

(51) Int. Cl. H10D 8/01; H10D 62/85; H10D 62/854

(52) U.S. Cl. CPC H10D 8/051; H10D 62/8503; H10D 62/854

(57) ABSTRACT

An exemplary embodiment of the present disclosure provides a device, a substrate and a doped material. The doped material comprises a group III metal nitride, and one of a p-type dopant or an n-type dopant. The doped material is disposed upon the substrate at a temperature below 1000° C. and comprises an increased dopant concentration. Also disclosed herein are methods for producing doped group III metal nitride produces comprising flowing a plasma comprising nitrogen from a remote plasma chamber into a growth chamber; introducing a group III metal and at least one of a p-type dopant or an n-type dopant into the growth chamber; and disposing, over a substrate at a temperature below about 1000° C., a conductive group III metal nitride product comprising an increased electrical carrier concentration.

### CROSS-REFERENCE TO RELATED APPLICATIONS

This application claims the benefit of U.S. Provisional Application Ser. No. 63/298,387, filed on 11 Jan. 2022, and U.S. Provisional Application Ser. No. 63/298,424, filed on 11 Jan. 2022, both of which are incorporated herein by reference in its entirety as if fully set forth below.

### FEDERALLY SPONSORED RESEARCH STATEMENT

This invention was made with government support under grant/award number N00014-18-1-2429, awarded by the Office of Naval Research and FA9550-21-1-0318, awarded by the Air Force Office of Scientific Research. The government has certain rights in the invention.

### FIELD OF THE DISCLOSURE

The various embodiments of the present disclosure relate generally to methods of doping group III metal nitrides and systems having conductive p-type and/or n-type doped group III metal nitrides, and more particularly to methods of growing aluminum nitride with dopants at low temperatures using cyclic pulsing of both group III metals and p-type or n-type dopants and a diode constructed from combining regions of p-type doping and regions of n-type doping with optional interior regions.

### BACKGROUND

Nitride based semiconducting materials made from group III metals and nitrogen have broad applications in diodes, light-emitting diodes (LEDs), solar cells, photodetectors, high electron mobility transistors (HEMTs), and laser diodes due to the wide range of energy bandgaps. Depending on the group III metal, the energy bandgap ranges from about 0.65 eV to about 6.1 eV, which span a photon absorption range from about 2 m (infrared) to about 200 nm (ultraviolet). Semiconducting materials can alter the composition of Group III elements relative to each other in such a way that the sum of group III elements equals the sum of nitrogen (e.g., AlₓIn_{y}Ga_{1-x-y}N where x≤1, y≤ and x+y≤1 where N has an unwritten subscript of 1) so as to modulate the energy bandgap and thus, the emission energy and wavelength as well as important electrical properties like voltage for which the material breaks down and conducts electricity. Semiconducting materials can be doped with trace electron-donor dopant atoms (n-type) or electron-acceptor dopant atoms (p-type) to augment the electrical, optical, and structural properties of the resulting device.

Despite a wide variety of theorized dopants, dopants useful for achieving substantial conductivity, conductivity useful for electronic and optoelectronic devices without excessive resistance losses, have not been experimentally realized for extreme bandgap semiconductors including AlN.

Silicon or germanium are theorized to be good n-type dopants for wide-bandgap materials. For ultra-wide bandgap (UWBG) semiconductors whose bandgap is generally ˜4.5 eV or above, doping becomes extremely difficult leading to high resistance or even insulating behavior. These ultra-wide-bandgap semiconductors such as AlN and AlN based semiconductors, alloys with bandgaps close to AlN, are well-known insulators and converting such materials to doped semiconductors has been challenging due to the limitations of typical doping methods.

Beryllium (Be) is one such dopant theorized to be one of the best p-type dopants for wide-bandgap nitride based semiconductor materials (e.g., gallium nitride, aluminum nitride, or indium nitride and the alloys such as AlₓIn_{y}Ga_{1-x-y}N, where x≤1, y≤ and x+y≤1, constructed by the binary nitride permutations). But despite several theoretical studies supporting Be's use as an acceptor dopant, substantial p-type conduction using Be has not been realized in any nitride semiconductor.

Metalorganic chemical vapor deposition (MOCVD) is a method used to deposit single or polycrystalline thin films and requires high temperatures and moderate pressures to form alloys. Molecular-beam epitaxy (MBE) grows crystals through physical vapor evaporation or sublimation but requires the growth of single crystal thin films in a high vacuum, high temperature environment. Both MBE and MOCVD operate at elevated substrate temperatures well above the desorption temperatures for wide-bandgap semiconductors like group III metal nitrides. This excessive heat load leads to an increase in epitaxy chamber outgassing of impurities and creates exponentially higher concentrations of vacancies within the growing crystal that can compensate doping. Substantial doping of bulk aluminum nitride (AlN) and extreme bandgap AlN-based semiconductors with either p-type or n-type dopants has not been successful due to the high temperatures of the MBE and MOCVD methods. The high temperatures of these methods result in excessive vacancies where dopants form defects within the crystal structure that take away from conduction instead of behaving as a dopant.

Therefore, there is a need for methods that can adequately dope group III metal nitrides such as AlN and AlN-based bandgap semiconductors, and open up the possibility for deep ultraviolet light emitting and light detecting applications or high-temperature, high-voltage, and high-power electronics.

### BRIEF SUMMARY

The present disclosure relates to methods of doping group III metal nitrides and systems having conductive p-type and/or n-type doped group III metal nitrides. An exemplary embodiment of the present disclosure provides a device comprising a substrate and a doped material. The doped material can comprise a group III metal nitride and one of a p-type dopant or an n-type dopant. The doped material can be disposed upon the substrate at a temperature below 1000° C. and can comprise an increased dopant concentration.

In any of the embodiments disclosed herein, the doped material can comprise one of the p-type dopant or the n-type dopant in a concentration ranging from about 1×10¹¹ cm⁻³ to about 3×10²⁰ cm⁻³.

In any of the embodiments disclosed herein, the doped material can further comprise a hole-carrier concentration ranging from about 1×10¹¹ to 1×10¹⁹ cm⁻³.

In any of the embodiments disclosed herein, the doped material can further comprise an electron-carrier concentration of at least 6×10¹⁵ cm⁻³ (e.g. from about 6×10¹⁵ cm⁻³ to about 3×10²⁰ cm⁻³).

In any of the embodiments disclosed herein, the doped material can be configured to achieve at least 100 thousand increased dopant concentration compared to a second group III metal nitride grown at a temperature greater than 1000° C.

In any of the embodiments disclosed herein, the doped material can further comprise a bandgap energy greater than 4.5 electronvolt (eV).

In any of the embodiments disclosed herein, the doped material can comprise a bandgap energy of approximately 6.1 eV.

In any of the embodiments disclosed herein, the doped material can be configured to emit one or more photons comprise a wavelength from about 200 nm to about 350 nm.

In any of the embodiments disclosed herein, wherein the group III metal nitride comprises a material selected from aluminum nitride (AlN), gallium nitride (GaN), aluminum gallium nitride (AlGaN), indium aluminum nitride (InAlN), aluminum scandium nitride (AlScN), indium gallium aluminum scandium nitride (InGaAlScN), or combinations thereof.

In any of the embodiments disclosed herein, the p-type dopant can comprise beryllium.

In any of the embodiments disclosed herein, the n-type dopant can comprise silicon.

In any of the embodiments disclosed herein, the device can further comprise a semiconductor disposed upon the doped material.

In any of the embodiments disclosed herein, the doped material can be disposed upon the semiconductor to form a homojunction.

In any of the embodiments disclosed herein, the doped material can be disposed upon the semiconductor to form a heterojunction.

In any of the embodiments disclosed herein, the device can be configured to disrupt viral and bacterial replication.

In any of the embodiments disclosed herein, the device can be configured to enhance polymer curing.

In any of the embodiments disclosed herein, the substrate can comprise sapphire, crystalline-silicon, gallium nitride, gallium oxide, aluminum nitride, aluminum gallium nitride, zinc oxide, lithium gallate, lithium aluminate, single crystal diamond, heteroepitaxial single crystal diamond, silicon carbide, or combinations thereof.

An exemplary embodiment of the present disclosure provides a method for growing a conductive group III metal nitride product. The method can comprise flowing a plasma comprise nitrogen from a remote plasma chamber into a growth chamber, introducing a group III metal and at least one of a p-type dopant or an n-type dopant into the growth chamber, and disposing, over a substrate at a temperature below about 1000° C., a conductive group III metal nitride product comprise an increased electrical carrier concentration.

In any of the embodiments disclosed herein, the method can further comprise, by the conductive group III metal nitride product, a hole-carrier concentration of at least 1×10¹¹ cm⁻³ (e.g. from about 1×10¹¹ cm⁻³ to about 1×10¹⁹ cm⁻³).

In any of the embodiments disclosed herein, the method can further comprise, by the conductive group III metal nitride product, an electron-carrier concentration of at least 6×10¹⁵ cm⁻³ (e.g. from about 6×10¹⁵ cm⁻³ to about 3×10²⁰ cm⁻³).

In any of the embodiments disclosed herein, the method can further comprise achieving, by the conductive group III metal nitride product, an increased electrical carrier concentration of at least 100 thousand times compared to a second group III metal nitride product grown at a temperature greater than 1000° C.

In any of the embodiments disclosed herein, the conductive group III metal nitride product can comprise a material selected from aluminum nitride (AlN), gallium nitride (GaN), aluminum gallium nitride (AlGaN), indium aluminum nitride (InAlN), aluminum scandium nitride (AlScN), indium gallium aluminum scandium nitride (InGaAlScN), or combinations thereof.

In any of the embodiments disclosed herein, introducing the p-type dopant or the n-type dopant into the growth chamber can further comprise pulsing one or more fluxes of the respective dopant.

In any of the embodiments disclosed herein, introducing the p-type dopant or the n-type dopant into the growth chamber can further comprise pulsing one or more fluxes of a group III metal with a constant nitrogen supply.

In any of the embodiments disclosed herein, the pulsing of the respective dopant can further comprise delivering for a delivery period ranging from about 0.1 seconds to about 30 seconds.

In any of the embodiments disclosed herein, the pulsing of the respective dopant can further comprise pausing for a paused period ranging from about 1 second to about 30 seconds.

In any of the embodiments disclosed herein, the pulsing of the respective dopant can further comprise delivering for a delivery period ranging from about 1 second to about 25 seconds and pausing for a paused time period ranging from about 2 seconds to about 15 seconds.

In any of the embodiments disclosed herein, the temperature can comprise a range from about 600° C. to about 900° C.

In any of the embodiments disclosed herein, growing a group III metal nitride product can further comprise a III/V flux ratio equal to or greater than about 1.

In any of the embodiments disclosed herein, the III/V ratio can range from about 1.1 to 1.5.

In any of the embodiments disclosed herein, when introducing the p-type dopant into the growth chamber, the temperature can comprise a range from about 500° C. to about 850° C.

In any of the embodiments disclosed herein, the temperature can comprise a range from about 600° C. to about 700° C.

In any of the embodiments disclosed herein, growing a group III metal nitride product can further comprise a III/V ratio equal to or greater than about 1.5.

In any of the embodiments disclosed herein, the III/V ratio can range from about 1.6 to 2.0.

In any of the embodiments disclosed herein, when introducing the n-type dopant into the growth chamber, the temperature can include a range from about 500° C. to about 1000° C.

In any of the embodiments disclosed herein, the temperature can comprise a range from about 600° C. to about 800° C.

In any of the embodiments disclosed herein, the method can further comprise constructing a diode comprise the conductive group III metal nitride product.

In any of the embodiments disclosed herein, the method can further comprise constructing a transistor comprise the conductive group III metal nitride product.

In any of the embodiments disclosed herein, the method can further comprise emitting one or more photons comprise a wavelength from about 200 nm to about 350 nm.

In any of the embodiments disclosed herein, the method can further comprise disinfecting a surface from a virus or bacterium.

An exemplary embodiment of the present disclosure provides a diode comprising a substrate, a first doped group III metal nitride disposed on the substrate, and a second doped group III metal nitride disposed on at least a portion of the first doped group III metal nitride.

The first doped group III metal nitride can comprise a higher concentration of electrical carriers than the second doped group III metal nitride. The first doped group III metal nitride and second doped group III metal nitride can be grown at a temperature below 1000° C.

In any of the embodiments disclosed herein, can further comprise a Schottky barrier electrode disposed on at least a portion of the second doped group III nitride.

In any of the embodiments disclosed herein, the diode can further comprise an ohmic electrode disposed on at least a portion of the first doped group III-nitride.

In any of the embodiments disclosed herein, the first doped group III metal nitride can comprise a first electrical-carrier concentration in a range from about 5×10¹⁷ cm⁻³ to about 3×10²⁰ cm⁻³.

In any of the embodiments disclosed herein, the diode, the second p-doped group III metal nitride comprising a second electrical-carrier concentration in a range from about 1×10¹⁵ cm⁻³ to 3.1×10¹⁵ cm⁻³.

In any of the embodiments disclosed herein, the diode, the second p-doped group III metal nitride comprising a second electrical-carrier concentration in a range from about 1×10¹⁵ cm⁻³ to 5×10¹⁹ cm⁻³.

An exemplary embodiment of the present disclosure provides a diode comprising a substrate, a first n-doped group III metal nitride disposed on the substrate at a temperature at or below 800° C., and a p-doped group III metal nitride disposed on the n-doped group III metal nitride at a temperature at or below 700° C., the diode can be configured to achieve a turn-on voltage of approximately 6 volts (V).

In any of the embodiments disclosed herein, the first n-doped group III metal nitride can comprise an electron-carrier concentration of at least 1×10¹⁷ cm⁻³ (e.g. from about 1×10¹⁷ cm⁻³ to about 3×10²⁰ cm⁻³).

In any of the embodiments disclosed herein, the p-doped group III metal nitride can comprise a hole-carrier concentration of at least 1×10¹⁷ cm⁻³ (e.g. from about 1×10¹⁷ cm⁻³ to about 3×10²⁰ cm⁻³).

In any of the embodiments disclosed herein, the diode can further comprise a second n-doped group III metal nitride grown between the first n-doped group III metal nitride and the p-doped group III metal nitride.

In any of the embodiments disclosed herein, the second n-doped group III metal nitride can comprise an electron-carrier concentration lower than the first n-doped group III metal nitride.

In any of the embodiments disclosed herein, the second n-doped group III metal nitride can be configured to function as an unintentionally doped layer.

In any of the embodiments disclosed herein, the second n-doped group III metal nitride can be configured to have an energy bandgap smaller than an energy bandgap of the first n-doped layer or the p-doped layer.

In any of the embodiments disclosed herein, the second n-doped group III metal nitride can comprise alternating wells. The wells can comprise an energy bandgap smaller than the energy bandgap of the first n-doped layer or the p-doped layer.

In any of the embodiments disclosed herein, the second n-doped group III metal nitride can further comprise alternating barriers, The barriers can be interspersed between the wells. The barrier can comprise an energy bandgap larger than the energy bandgap of the wells.

In any of the embodiments disclosed herein, the barriers can further comprise an energy bandgap equal to or less than the energy bandgap of the first n-doped layer or the p-doped layer.

In any of the embodiments disclosed herein, the diode can be configured to emit one or more photons comprising a wavelength from about 200 nm to about 350 nm.

In any of the embodiments disclosed herein, the diode can further comprise an optically reflective surface configured to internally reflect one or more photons.

In any of the embodiments disclosed herein, the diode can further comprise a rough surface configured to reduce internal reflection.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1 is a prospective schematic diagram of a material or device having additional metallic layers on the surface of the crystal to facilitate increased charge carrier concentration and growth at a temperature below 1000° C., in accordance with an exemplary embodiment of the present invention.

FIG. 2A is a prospective schematic diagram of a vertical group III metal nitride Schottky diode, in accordance with an exemplary embodiment of the present invention.

FIG. 2B is a prospective schematic diagram of a quasi-vertical group III metal nitride Schottky diode, in accordance with an exemplary embodiment of the present invention.

FIG. 2C is a prospective schematic diagram of a p-type group III metal nitride, in accordance with an exemplary embodiment of the present invention.

FIG. 3A is a schematic illustration of a crystal structure of a group III metal nitride showing the incorporation of Be (atomic radius of ˜112 pm) as a p-type substitutional impurity replacing Al (atomic radius of ˜118 pm), in accordance with an exemplary embodiment of the present invention.

FIG. 3B is a schematic illustration of a crystal structure of a group III metal nitride showing the incorporation of Si (atomic radius of ˜111 pm) as an n-type substitutional impurity substituting Al (atomic radius of ˜118 pm), in accordance with an exemplary embodiment of the present invention.

FIG. 4A depicts aspects of current-voltage characteristics of Pt (10 nm)/Pd (10 nm)/Au (100 nm) contacts on an example group III metal nitride device with dopants, in accordance with an exemplary embodiment of the present invention.

FIG. 4B depicts aspects of current-voltage characteristics of Pt (10 nm)/Pd (10 nm)/Au (100 nm) contacts on an example group III metal nitride device without dopants, in accordance with an exemplary embodiment of the present invention.

FIG. 5 depicts aspects of p-contacts transmission line measurement (PTLM) of an example group III metal nitride device with dopants, in accordance with an exemplary embodiment of the present invention.

FIG. 6A depicts aspects of n-contacts transmission line measurement (NTLM) of an example group III metal nitride device with dopants, in accordance with an exemplary embodiment of the present invention.

FIG. 6B depicts aspects of p-contacts transmission line measurement (PTLM) of an example group III metal nitride device with dopants, in accordance with an exemplary embodiment of the present invention.

FIG. 7A depicts aspects of current density-voltage JV characteristics of an example group III metal nitride device with dopants, in accordance with an exemplary embodiment of the present invention.

FIG. 7B depicts aspects of semilog current density-voltage JV characteristics of an example group III metal nitride device with dopants, in accordance with an exemplary embodiment of the present invention.

FIG. 8A depicts aspects of dopant SIMS concentration in an example group III metal nitride device grown at varying temperatures, in accordance with an exemplary embodiment of the present invention.

FIG. 8B depicts an Arrhenius plot of dopant SIMS concentration, illustrating exponential dependence of the doping within an example group III metal nitride device on the dopant effusion cell temperature, in accordance with an exemplary embodiment of the present invention.

FIG. 9 is a schematic diagram of an example group III metal nitride device illustrating open/close “O/C” times of the shutter sequence for the films during growth and the corresponding RHEED pattern indicating relatively smooth surface morphology of the films, in accordance with an exemplary embodiment of the present invention.

FIG. 10 depicts aspects of hole concentration plotted vs SIMS concentration with an average dopant activation efficiency of 5% in an example group III metal nitride device at a substrate temperature of 600° C., in accordance with an exemplary embodiment of the present invention.

FIG. 11 depicts aspects of activation energy of a dopant in an example group III metal nitride device, in accordance with an exemplary embodiment of the present invention.

FIGS. 12A through 12D show cross-sectional transmission electron microscope (TEM) images of an example group III metal nitride device before and after Al flashing, in accordance with an exemplary embodiment of the present invention.

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

As used herein, the terms “about” or “approximately” for any numerical values or ranges indicate a suitable dimensional tolerance that allows the part or collection of components to function for its intended purpose as described herein. More specifically, “about” or “approximately” may refer to the range of values ±20% of the recited value, e.g. “about 90%” may refer to the range of values from 71% to 110%.

It must also be noted that, as used in the specification and the appended claims, the singular forms “a,” “an” and “the” include plural referents unless the context clearly dictates otherwise.

Ranges can be expressed herein as from “about” or “approximately” one particular value and/or to “about” or “approximately” another particular value. When such a range is expressed, another embodiment includes from the one particular value and/or to the other particular value.

By “comprising” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

As mentioned supra, both MOCVD and MBE have successfully achieved moderately doped p-GaN using magnesium, Mg dopants. However, bulk Be doping resulted in semi-insulating GaN suitable for high power devices but highly p-type GaN could not be achieved due to the high experimental activation energy of (˜700 meV) of Be in GaN. The high activation energy of Be in GaN is due to strain resulting from the high atomic radius mismatch of Be (˜112 pm) vs Ga (˜136 pm) resulting in an undesirable interstitial Be instead of Ga substitutional site in the crystal lattice.

As compared to GaN, AlN is much harder to dope, especially p-type because Mg has a higher activation energy (˜510 meV) in AlN presumably due to the high atomic radii difference of Mg (˜145 pm) as compared to Al (˜118 pm). Be is a potentially suitable candidate for p-type doping of AlN due to the close atomic radii match of Be (A112 pm) to Al (A118 pm). Also AlN:Be has theoretically shown a much lower activation energy (330 meV) as compared to AlN:Mg. Unfortunately, Be is generally not used for MOCVD due to serious safety concerns. In comparison Be usage in MBE is generally safe and common practice.

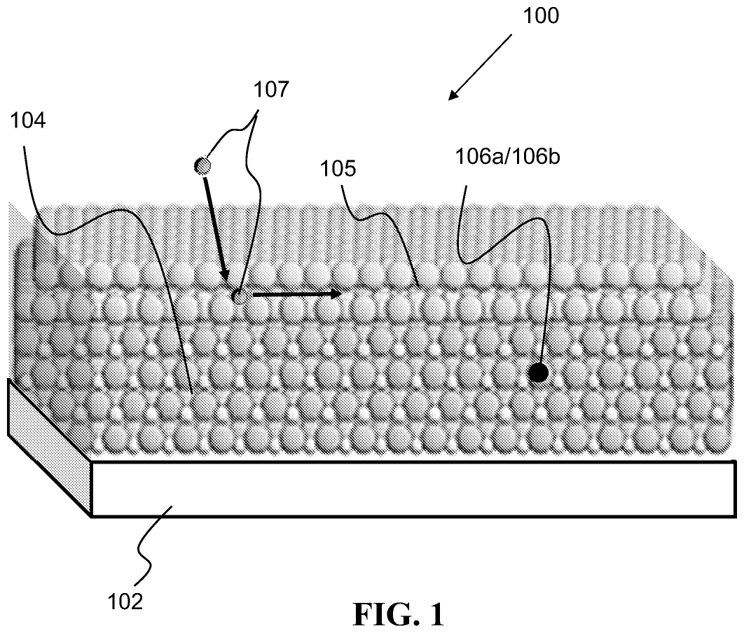

FIG. 1 provides an exemplary device 100 having a substrate 102 and a doped material 104 disposed upon the substrate 102. Doped material 104 comprises at least a layer of a group III metal nitride, such as aluminum nitride (AlN), gallium nitride (GaN), aluminum gallium nitride (AlGaN), indium aluminum nitride (InAlN), aluminum scandium nitride (AlScN), indium gallium aluminum scandium nitride (InGaAlScN). The group III metal nitride contains a group III metal rich surface 105 that lowers the energy barriers for surface diffusion relative to a N-rich surface typically used in MOCVD allowing substantially higher surface diffusion even at lower temperatures. This periodically accumulated then depleted metal rich surface 105 adlayer is created by supplying to the semiconductor surface a periodically modulated excess of metal compared to the constantly supplied nitrogen 107. During the portion of the cycle where the metal sources are disposed onto the semiconductor surface, an increase in the accumulated excess metal density (metals not yet bonded to a nitrogen atom) increases. The metal coverage is reduced, eventually and briefly to zero coverage during the portion of the cycle where the metal sources are not disposed onto the semiconductor surface. Due to the accumulated metal excess, even when the sources are not disposed on the semiconductor surface, the crystalline synthesis continues for all times except the brief moment when no group III metal exists on the surface. Contrary to MOCVD and MBE, the substrate temperature used is less than the desorption temperature of the metals ensuring that all metals applied to the surface are consumed without desorption. In this way, a very high growth rate and thus, a very low background impurity concentration is achieved as the impurity concentration is inversely related to the crystalline growth rate. Likewise, due to the existence of the accumulated excess group III surface metal, the lateral surface diffusion of nitrogen 107 is enhanced because atomic hopping of nitrogen 107 need only break weak metallic bonds, not strong semiconductor bonds. The nitrogen 107 can also diffuse vertically to the semiconductor—metal interface where a new epitaxial monolayer can be formed, extending the crystal upward (away from the substrate). This enhanced lateral diffusion accomplished using metal rich surfaces 105 results in improved crystal quality even at lower temperatures than other methods, allowing less heat load and thus less contamination for the growth system. This repetitive cycle of group three metals first disposed on the surface, then no metals disposed on the surface is repeated with a constant nitrogen 107 supply resulting in the conversion of a portion of this accumulated metal converted to a group III metal nitride semiconductor. The group III metal nitride is doped with at least one of a p-type dopant 106a or an n-type dopant 106b. Doped material 104 is grown at a temperature at or below 1000° C. for AlN and even lower temperatures for group III alloys of AlN such that the p-type dopant 106a or the n-type dopant 106b can diffuse through the metal rich surface 105 of the group III metal nitride to generate an increased dopant concentration inside the film first incorporating at the metal-semiconductor interface and eventually being buried by subsequently grown semiconductor adlayers. Doped material 104 with an increased dopant concentration can be grown through metal-modulated epitaxy (MME). Examples of systems and methods for group III metal nitride growth with MME are disclosed in U.S. Pat. Nos. 10,526,723, and 11,319,644, each of which are incorporated herein by reference as if set forth fully below.

Although not depicted in the figures, adding dopants (the elements Be, Si etc.,) into a crystal of group III metal nitrides can be done at any temperature, but doing so results in dopants that act as insulators rather than active charge carriers. The systems and methods described herein result in electrically active dopants throughout doped material 104. In other words, doped material 104 grown at a temperature at or below 1000° C. results in active dopants 106 that can either (i) donate an electron providing a free electron, or (ii) capture an electron providing a free hole.

Unlike traditional molecular beam epitaxy (MBE), the method described herein, metal modulated epitaxy (MME) has three growth parameters: substrate temperature, III/V ratio, and excess-metal dose per shutter cycle, enabling it to have more growth control.

The substrate temperature is set to a temperature below about 1000° C. (e.g., below about 950° C., below about 900° C., below about 850° C., below about 800° C., below about 750° C., below about 700° C., below about 650° C., below about 600° C., below about 550° C., below about 500° C., and any value in between, e.g., below about 834° C.). Low substrate temperature decreases contamination from gaseous outgassing and helps control surface chemistry and kinetics to facilitate proper incorporation of active dopants within the group III metal nitride material. In some embodiments, growth of a p-type semiconductor with increased concentrations of active charge carriers, the substrate temperature is set to a temperature range between about 500° C. to about 900° C., and preferably between about 600° C. and about 700° C. For growth of n-type semiconductors with increased concentrations of active charge carriers, a substrate temperature range is set between about 500° C. to about 1000° C., and preferably between about 600° C. and about 800° C.

Substrate 102 can include any suitable semiconductor-substrate material including, for example, sapphire, crystalline-silicon, gallium nitride, gallium oxide, aluminum nitride, aluminum gallium nitride, zinc oxide, lithium gallate, lithium aluminate, single crystal diamond, heteroepitaxial single crystal diamond, silicon carbide, or combinations thereof.

The III/V ratio means the concentration ratio of a column 3 metal to a column 5 element, such as nitrogen, where a III/V ratio is preferably greater than 1 and less than 2. For a p-type AlN-containing semiconductor, a III/V ratio closer to 1 (e.g., about 1.5, about 1.4, about 1.3, about 1.2, about 1.1, or about 1.01) is ideal, while for an n-type AlN-containing semiconductor, a III/V ratio closer to 2 (e.g., about 1.5, about 1.6, about 1.7, about 1.8, about 1.9, or about 2.0) is preferred.

Excess-metal dose per shutter cycle means a higher concentration of metal (compared to nitrogen) permitted to accumulate on the surface of the substrate for more time based on the shutter open/close cycle times. In some embodiments, metal modulated epitaxy varies the metal fluxes while keeping the nitrogen flux constant throughout the growth. Growth occurs during the metal shutter open cycle (if more than one metal is used as in a AlN based alloy, both metal shutters can be simultaneously opened) and after the shutters are closed during the part of the cycle where the accumulated metals are consumed. However, growth then momentarily stops before the beginning of the next cycle. In the methods described herein, both the group III metal and the dopant can be introduced for a delivery period from about 0.1 seconds to about 30 seconds (e.g., from about 0.5 seconds to about 28 seconds, from about 1.0 seconds to 26 seconds, from about 1.5 seconds to about 24 seconds, from about 2.0 seconds to 22 seconds, from about 2.5 seconds to about 20 seconds, from about 3.0 seconds to 18 seconds, from about 3.5 seconds to about 16 seconds, from about 4.0 seconds to 15 seconds, from about 4.5 seconds to about 14 seconds, from about 5.0 seconds to 12 seconds, and any time interval in between, e.g., from about 8.24 seconds to about 29.98 seconds). In addition, the shutter can close to pause introduction of the group III metal(s) and the dopant for a paused period ranging from about 1 second to about 30 seconds (e.g., from about 1.5 seconds to about 28 seconds, from about 2.0 seconds to 26 seconds, from about 2.5 seconds to about 24 seconds, from about 3.0 seconds to 22 seconds, from about 3.5 seconds to about 20 seconds, from about 4.0 seconds to 18 seconds, from about 4.5 seconds to about 16 seconds, from about 5.0 seconds to 15 seconds, from about 5.5 seconds to about 14 seconds, from about 6.0 seconds to 12 seconds, and any time interval in between, e.g., from about 4.17 seconds to about 27.34 seconds).

As would be appreciated by one of skill in the art, because of the interplay of defects that compensate charge carriers and have in the past prevented substantial conductivity in AlN and AlN based semiconductor alloys, adjusting any one of the three parameters for MME of AlN-doped material can adjust the amount of charge carrier concentration that generates the AlN semiconductor. Likewise, increasing or decreasing the flux of dopants to the surface will raise or lower the charge carrier concentration. Various examples of such are discussed in more detail with respect to the Examples section herein.

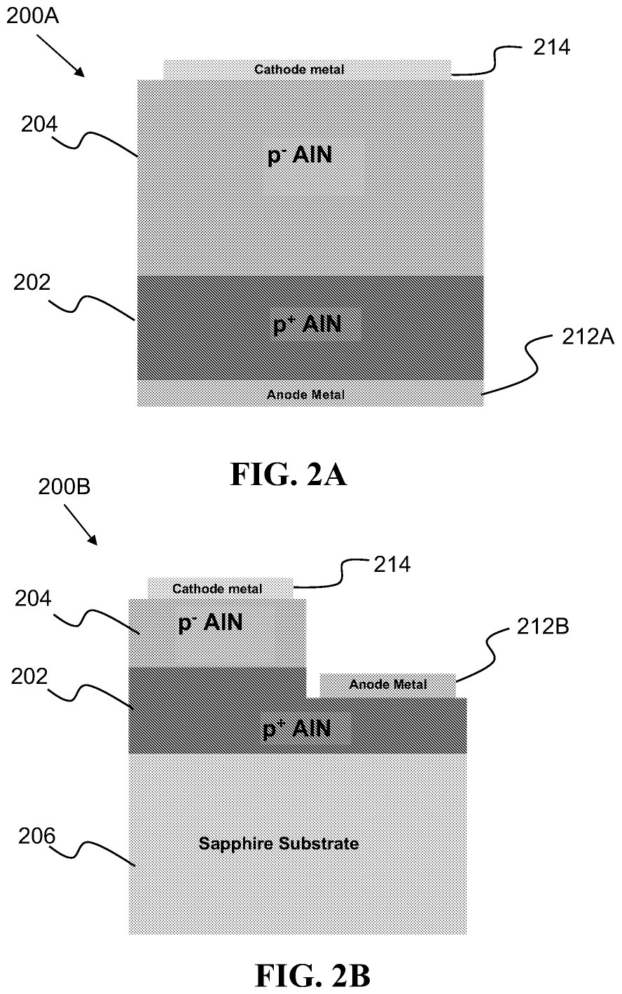

FIG. 2A is a prospective schematic diagram of an exemplary vertical group III metal nitride Schottky diode. As shown, first semiconductor 202 having a wide, ultra-wide, or extreme energy bandgap and one of a p-type dopant or an n-type dopant, wherein the first semiconductor 200 comprises a dopant concentration ranging from about 1×10¹⁵ to 5×10²⁰ cm⁻³ or from about 5×10¹⁷ to 7×10¹⁹ cm⁻³. The first semiconductor 202 can be grown through the methods and processes described in more detail below. Although not pictured, device 200A can be made of one or more layers of n-type or p-type doped first semiconductor 202 that results in a conductive wide, ultra-wide, or extreme energy bandgap material.

Alternatively or in addition thereto, device 200A, 200B can be layered into a structure having a second semiconductor 204. Second semiconductor 204 can be of the same semiconductor materials as the first semiconductor 202. For instance, when first semiconductor comprises aluminum nitride (AlN), the second semiconductor can be of the same or similar AlN. In such a case, when the first and second semiconductors 202, 204 are of similar semiconductor material, a homojunction at the interface between the layers can form. In particular, a homojunction can have equal bandgaps but have differing doping levels.

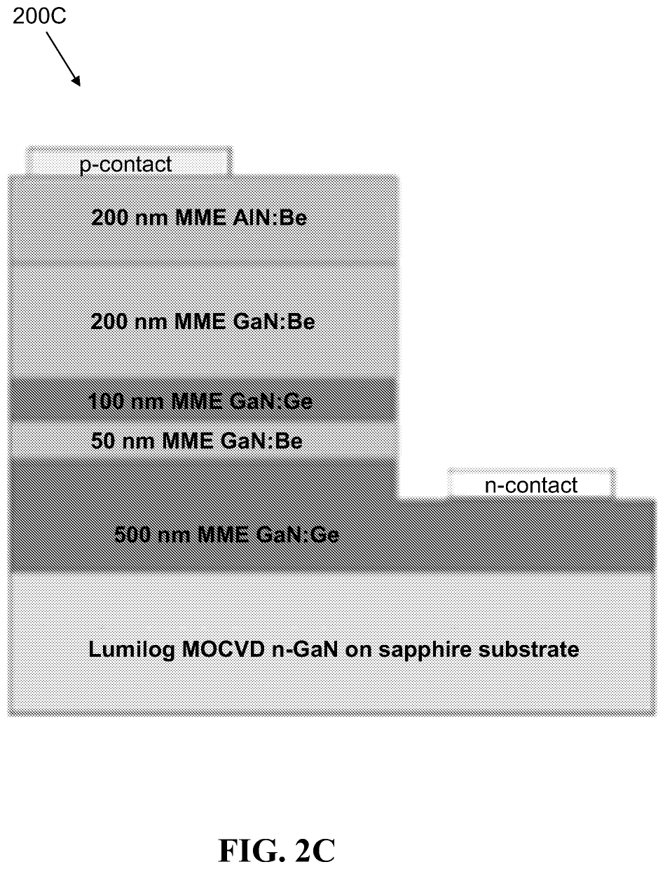

As described herein and shown in FIGS. 2A and 2B, first semiconductor 202 can have a higher concentration of p-type dopant (“p+” in FIGS. 2A and 2B, and as shown in more detail in FIG. 3A) while second semiconductor 204 can have lower concentration of p-type dopant (“p-” in FIGS. 2A and 2B). The lightly p-type doped semiconductor may be grown on top of the heavily p-type doped semiconductor to provide a better cathode (or anode for n-type) contact with improved electrical breakdown performance. Lowering the dopant concentration or by increasing the thickness of layer 204 can increase the breakdown voltage of the Schottky Diode.

In some embodiments, device 200A can be layered into a fully vertical Schottky diode having an anode metal or alloy 212A contacting the first semiconductor 202 and a cathode metal or alloy 214 contacting the second semiconductor 204, where the anode 212A and cathode 214 contacts are on opposite or opposing sides of the device 210A. In some embodiments, and as shown in FIG. 2B, device 200B can be layered into a quasi-vertical AlN Schottky diode with the anode 214B and cathode 214 contacts on the same side of device 200B.

The anode metal or alloy 212A, 212B of device 200A, 200B can be a high work function metal, alloy, or multi-metal stack for p-type embodiments or low work function metal, or multi-metal stack for n-type embodiments, such as, for example, comprised of Ni, Pt, Pd, Ti, Al, Sc, Y, Nb, Au, or combinations thereof. Anode 212A, 212B can be annealed to first semiconductor 202 to better form an ohmic contact.

The cathode metal or alloy 214 of device 200A, 200B, 200C can be chosen to have a high barrier height to the second semiconductor 204. The cathode 214 can be a low or lower work function metal, alloy, or multi-metal stack, such as, for example, Al, Mg, Ti, alkali metals, or combinations thereof.

Although FIGS. 2A and 2B show one arrangement of p-type diodes, it is understood in some embodiments n-type materials can be used instead of the p-type materials. In these embodiments the anode and cathode electrodes are reversed as are the choices of metals based on high or low work function.

Additionally, a semiconductor material can be layered with a different semiconductor material to enhance certain properties of the combined material, and in doing so, form junctions where the first semiconductor material touches the second semiconductor material. Typical diode devices rely on junctions from abutting semiconducting materials, including p-n junctions, n-p junctions, or p-i-n junctions. One of the benefits of a diode having a junction includes easier electric charge flow in one direction while blocking current flow in the opposing direction, useful in producing a direct current. In general, electrons can easily flow through the junction from the n-layer to the p-layer, whereas holes can easily flow through the junction from the p-layer to the n-layer. Since wider bandgaps result in higher electrical breakdown voltages for a given thickness, i.e. higher breakdown fields, rectifiers with much larger blocking voltages can be produced. Without being bound by any scientific theory, this is a substantial improvement in the current invention since AlN has the highest bandgap of any semiconductor that has ever been substantially doped and was not substantially doped until the method described here was developed. Additionally, various intervening layers can replace the i-layer in a p-i-n junction to form optical and electronic devices well known the art. For example, the i-layer can be replaced with one or more regions of lower energy bandgap material suitable for trapping electrons and holes, thus enhancing light emission and efficiency. If more than one light producing layer is inserted, they may be separated by wider bandgap layers that can themselves have varying levels of doping. Similarly, one or more layers can be introduced that not only emit light from one or more of the light producing layers but have optical indexes of refraction suitable to guide the light and allow stimulated light emission, i.e. lasing. Still another option is to provide p-n junctions where the electric field modulates the carrier concentration in a semiconductor region as in a transistor. It is recognized by those skilled in the art that the enablement of this p- and n-type conduction also enables a wide variety of functional devices.

In some embodiments, devices including MME-grown p-type conduction from Be doped AlN may be used to produce high temperature, high voltage transistors and DUV photodetectors and light sources. UV effectiveness for DNA disruption of viruses and bacteria peaks around 270 nm and 200 nm, while protein absorption is low at 270 nm and increases toward 200 nm. Because AlN presents a bandgap energy around 6.1 eV, a device with doped AlN may emit around 203 nm.

Although not depicted, doped material 104 with increased active dopant concentration dispersed throughout a group III metal nitride can be used to form common semiconductor diode devices (e.g., a PIN diode, a Schottky diode, a transient-voltage-suppression diode, a tunnel diode, a Zener diode, a Gunn diode, a laser diode, an LED, a photocell, a phototransistor, a solar cell, an IMPATT diode, and the like) as well as transistor devices (e.g., field-effect transistor, metal insulator semiconductor field effect transistor (MISFET), high-electron-mobility transistor (HEMT), and the like). For instance, group III metal nitride layers with increased active charge carriers can form a PIN diode, where the layers are grown by the MME methods described herein, with a homojunction with a layer functioning as an insulator or an unintentionally doped layer. As used herein, an unintentionally doped layer means that the grown layers behave as if they were not doped. In some examples, unintentionally doped GaN layers are inherently n-type due to residual defects with an electron-concentration of 10¹⁵-10¹⁷ cm⁻³. The dominant donor has not been unambiguously identified, but residual oxygen and native defects like nitrogen vacancies are commonly considered to be the sources of n-type conductivity.

In some embodiments, a device can be layered into a structure having a first semiconductor of a different semiconducting material than the second semiconductor. For instance, when first semiconductor comprises aluminum nitride (AlN), the second semiconductor can be of GaN. In such a case, when the first and second semiconductors are of different semiconducting material, a heterojunction at the interface between the layers can form. In particular, a heterojunction can have unequal bandgaps as well as differing doping type and concentration or similar doping type and concentration. As would be appreciated by those of skill in the art, varying the semiconducting material, doping type, group III composition, and dopant concentration can alter properties of the semiconducting material to generate devices for deep ultraviolet light emitting and light detecting applications or high-temperature, high-voltage, and high-power electronics. For instance, a typical LED can be p-AlN/I or n-AlGaN/n-AlN or can utilize multilayers of AlGaN of alternating bandgap interposed between the p and n-type AlN regions. By combining p-type regions adjacent to n-type regions, with optional intervening layers, a rectifying diode can be formed. An example device 200C in FIG. 2C provides n-type GaN, doped with Ge and grown through the MME methods described herein with a layer of p-type GaN, doped with Be grown over the first layer providing an “i” layer. In addition, FIG. 2C provides an example of additional layers combining p-type adjacent to n-type regions (e.g., an n-type GaN doped with Ge, followed by a p-type GaN doped with Be, followed by a p-type AlN doped with Be).

Because the doping of the semiconductor can be varied, the forward conduction and reverse breakdown voltage of the Schottky, PN or PIN diode can be controlled for a range of high-power diode applications. Furthermore, the selection of anode and cathode metals would give an additional control of the forward conduction and reverse breakdown voltage of the diodes.

In some embodiments, devices having an n-type and/or a p-type doped nitride-based semiconductor can be made by a method including introducing gas or a plasma-excited gas containing N atoms into a melt of a metal alloy deposited on the surface of a crystalline substrate, epitaxially growing nitride-based crystals on the seed crystal substrate at a temperature range below about 1000° C., introducing one or more fluxes of a metal and a dopant in a pulsed cyclical manner, and incorporating the dopant into the nitride-based crystals.

Gas or plasma-excited gas containing nitrogen atoms can be flowed constantly through growth chamber in order to allow nitrogen to react with the metal alloy melt. Metal alloy melts can include group III elements in the first column of the p-element block of the periodic table, including boron (B), aluminum (Al), gallium (Ga), indium (In), thallium (Tl)), or a combination thereof. Additional metal alloys are contemplated scandium (Sc) and yttrium (Y).

Epitaxially growing nitride-based crystals can include continual or almost continual growth of the semiconductor in thin atomic layers. The metal and dopant can be cycled together or can be cycled independently. The metal and dopant are pulsed into the chamber when a shutter opens to permit the one or more fluxes of the metal and dopant to incorporate into the growing crystals or semiconductor. When the metal and dopant shutters are open, excess metal and dopants can accumulate on the crystal or semiconductor surface continuing to grow. Metal-rich surfaces form during epitaxial growth at temperatures below 1000° C. When the metal and dopant shutters are closed, the excess metal and dopants can be consumed or adsorbed into the crystal or semiconductor layer, continuing the growth of the crystals or semiconductor layer. In some embodiments, after closing the metal and dopant shutters, a brief period of paused growth may occur so as to allow the semiconductor to be annealed under a nitrogen-plasma.

The temperature of doped crystal or semiconductor growth is substantially lower than traditional methods of growing crystals or semiconductors. In some embodiments, epitaxially growing nitride-based crystals or semiconductors on the seed crystal substrate can include a growth temperature below about 1000° C. The method described herein can generate conductive doped nitride-based semiconductors when growing at a temperature ranging from about 600° C. to about 1000° C. (e.g., from about 650° C. to about 950° C., from about 700° C. to about 900° C., from about 750° C. to about 850° C., or any range between, e.g., from about 738° C. to about 860° C.).

In some embodiments, nitride-based semiconductors can include only column III elements and nitrogen (e.g., AlN, GaN, InN, ScN, AlGaN, InAlN, ScInGaAlN, and the like). In some embodiments, metal-nitride alloys outside of the column III may be used for creating conductive semiconductor alloys, such as, for example, antimony(III) nitride, barium nitride, bismuth nitride, cadmium nitride, cesium nitride, calcium nitride, cerium nitride, chromium nitride, cobalt(III) nitride, copper(I) nitride, gold(III) nitride trihydrate, lead nitride, lithium nitride, magnesium nitride, mercury nitride, plutonium nitride, potassium nitride, rhenium nitride tetrafluoride, rubidium nitride, silver nitride, sodium nitride, thallium(I) nitride, uranium(III) nitride, zirconium nitride, or combinations thereof.

The ratio of metal to dopant can vary from about 99.9999% metal to about 0.0001% dopant (e.g., from about 99% metal to about 1% dopant, from about 99.9% metal to about 0.1% dopant, from about 99.99% metal to about 0.01% dopant, and any composition in between, e.g., from about 99.63% metal to 0.37% dopant).

As disclosed herein, ˜6000 times higher bulk AlN electron concentrations and ˜300,000,000 times higher AlN hole concentration are achieved at room temperature as compared to prior art {Taniyasu, Y., Kasu, M. & Makimoto, T. An aluminum nitride light-emitting diode with a wavelength of 210 nanometers. Nature 441, 325-328 (2006). https://doi.org/10.1038/nature04760}. With this successful experimental achievement of both n-type AlN:Si films and p-type AlN:Be films, the first-ever substantially doped AlN homojunction PIN diodes are demonstrated. The evidence of 6 orders of magnitude rectification with the proper turn on voltage of ˜6 V for a 6.1 eV AlN semiconductor (compared to over 20+ volts for the prior art) offers ultimate confidence that the pioneering doping results shown are in fact real. A new semiconducting AlN era has thus emerged with AlN no longer being simply an insulator. By simply modifying the internal layer (a layer can have many sublayers), i.e. the layer or layers between the n-type region and the p-type region, this embodiment demonstrates near-future exciting promise for AlN-based Deep Ultraviolet (DUV) optical emitters and detectors, high-power/voltage/temperature and high-frequency switching devices capable of operation in extreme radiation and heat environments.

The following examples further illustrate aspects of the present disclosure. However, they are in no way a limitation of the teachings or disclosure of the present disclosure as set forth herein.

### EXAMPLES

### Example 1—p-Type and n-Type Conductivity of AlN

One of the major limitations in achieving AlN based electronic devices is its lack of doping, making its theoretical potential for power switches irrelevant and resulting in GaN, β-Ga₂O₃ and SiC being used for power devices instead. P-type conductivity of AlN was a major challenge where reports of surface conductivity via carbon doping were shown {K. Kishimoto, M. Funato, Y. Kawakami, Applied Physics Express 2020, 13, 015512}but no substantial bulk experimental conductivity had been demonstrated in the prior art, the best being Taniyasu et al who achieved a technically irrelevant ˜10¹⁰ cm⁻³ room temperature hole concentration using Mg doped AlN grown by high temperature MOCVD. Be is the best possible p-type candidate in AlN because the Be—N bond energies and atomic radius of Be closely matches with Al as shown in Table 1 and shown in a schematic in FIG. 3A. For n-type AlN, Si is the best theoretical dopant as its atomic radius closely matches with Al as shown in FIG. 3B, and in Table 1 but prior work indicated that defect compensation limited room temperature electron concentrations to the 1-3×10¹⁵ cm⁻³ range {Taniyasu et al; M. L. Nakarmi, et al, Applied Physics Letters 2004, 85, 3769; T. Ive, et al, Applied Physics Letters 2005, 86, 024106; among others}

TABLE 1
Atomic radii of the III-nitride host atoms
and experimental p-type dopants.

| Element | Atomic radius (pm) |
|---|---|
| Al | 118 |
| Be | 112 |
| Si | 111 |
| O | 48 |
| N | 56 |

Using the methods disclosed herein, p-type Be doped AlN films were achieved with hole concentrations up to 3.1×10¹⁸ cm⁻³ via the improved growth kinetics of metal modulated epitaxy (MME) demonstrating high quality films at unconventionally low substrate temperatures. MME utilizes low substrate temperatures during growth to lower contamination normally resulting from gaseous outgassing and uses multiple parameters to control the surface chemistry and kinetics to facilitate proper incorporation of the dopants on the cation site. MME has also demonstrated the highest known hole concentrations for p-type GaN using Mg as a dopant. The MME AlN:Be p-type films were successfully applied to p-AlN/i-AlN/n-AlN diodes and p-AlN/i-GaN/n-GaN heterojunction Schottky, junction barrier Schottky (JBS) and Pin diodes. As described herein, it was found that ultra-high vacuum purity was key. Low background pressures during growth resulted in higher hole concentrations and less compensation.

Si as a substitutional impurity in AlN and results in a 6% theoretical relaxation of the nearest N-bonds. Promising results have been previously shown in the prior art for n-type doping of AlN near surface regions (non-bulk growth) by ion implantation; however, no more than 10¹⁵ cm⁻³ bulk electron concentrations were shown in n-type doping of bulk AlN films. This disparity in doping results with one technique showing viability and another not, suggests that Si itself is not the problem but some other defect/impurity related species is the impediment and other doping methods may be more appropriate. Si is a shallow donor in GaN with activation energy of 17 meV but its activation energy in AlGaN increases with Al content from 24 meV for Al_{0.85}Ga_{0.15}N to 211 meV for Al_{0.96}Ga_{0.04}N. The problem with doping AlN with Si can be understood by considering the atomic locations in which Si sits in the crystalline lattice. The solubility limit of a dopant depends on the formation energy of the dopants. Formation energy further depends on the atomic radii matching, the bond strength of the host vs dopant atoms and favorable geometric configurations of the dopant in the lattice. The traditionally measured activation energy of Si in AlN is above 200 meV due to the formation of Al vacancies, high threading dislocations trap electrons and DX center formation. The DX center forms when Si captures a secondary electron with a geometric rearrangement including a 2% contraction of 3 basil positioned Si—N bonds and the breaking of the c-axis Si—N bond as shown in FIG. 3B causing a transition from shallow to deep state. In the DX configuration shown in FIG. 3B, the Si atom stays close to the substitutional Al-site but shifts downward as the c-axis bond breaks resulting from the contraction of the nearest N-bonds. Complicating issues, the Al vacancy forms a complex with Si resulting in self-compensation of the doping at high Si doping levels. Likewise, oxygen is a donor in AlN at low concentrations resulting in a 4% theoretical elongation of the nearest N-bonds. But as shown in FIGS. 3A and 3B, at higher doping concentrations, oxygen also forms a DX center where the 0.19 nm basil AlN bonds shift to asymmetric lengths of 0.182, 0.182, and 0.175 nm and result in the diagonal displacement of O toward the open space in the crystal. This DX center reconfiguration forms a deep state at higher O concentrations compensating n-type AlN. Furthermore, this self-compensation was found to increase in magnitude with increases in threading dislocations. Thus, by growing the AlN films under highly crystalline conditions (reduced threading dislocations density) compensation of Si doping in AlN can be reduced. Vacancies, particularly Al vacancies act to increase the likelihood of DX center formation by allowing easier reconfiguration due to larger voids in the otherwise dense crystal structure and by forming Si-vacancy and O-vacancy complexes that also act as deep centers.

### Example 2—Metal Modulated Epitaxy

The method described herein, metal modulated epitaxy (MME), is a cyclic molecular beam epitaxy (MBE) derivative which operates in an ultra-high vacuum, extremely pure, low impurity outgassing environment limiting background carbon and oxygen to values typically in the 10¹⁵ to low 10¹⁷ cm⁻³ range. MBE or metal organic chemical vapor deposition (MOCVD) for III-Nitrides operates well above the desorption temperatures increasing epitaxy chamber outgassing of impurities and naturally creating exponentially higher concentrations of vacancies, N_{vacancies}, as governed by the vacancy production equation,

$$[ {N}_{Vacancies} ] = [ {N}_{Atomic} ] {Ce}^{- {E}_{formation} / kT}$$

where N_{Atomic} is the atomic concentration of the missing element, C is the number of equivalent configurations of the vacancy, and E_{formation} is the energy needed to form the vacancy including the net energy required from breaking and reconfiguring atomic bonds. Contrarily, MME operates well below the desorption temperatures and at metal rich surface conditions minimizing the vacancy production, especially for Al vacancies. MME compensates for the lower growth temperature with extremely metal rich surface chemistry that virtually eliminates the harmful Al vacancies and allows easier surface bond breakage and thus, long surface adatom diffusion lengths. For example, consider the surface diffusion equation:

$$Surface Diffusivity = [ {a}^{2} ( \frac{ω}{4} ) ] {e}^{- ∅ / kT}$$

where a is the hopping distance, ϕ is the energy barrier for hopping and ω is the vibrational frequency. Given the Metal-N barriers for hopping can be 15 times larger than for metal-metal surface hopping barriers, this barrier height discrepancy results in metal rich surfaces having 5-6 decades longer diffusion lengths than semiconductor bond rich surfaces like ammonia-based MBE or MOCVD. Even with 500 degrees difference in temperature between MOCVD and MME, the much lower hopping barrier height, 0.1-0.2 eV, results in a longer surface diffusivity for MME than N-rich MOCVD because the N-Rich barriers are ˜10-15 times higher. This difference in surface diffusion length is evident in MME (and most MBE) surface morphologies versus that of MOCVD. MME and metal rich MBE tend to show surfaces where spiral hillocks form around dislocations as the step flow growth is interrupted by the surface void found at dislocations. Conversely, MOCVD morphology is governed not by adatom diffusion but gas phase diffusion and conformally covers regions of dislocations resulting in a flat surface even in the presence of dislocations that disrupt step flow growth of atoms on the surface. When paired with MME's metal rich surfaces that increase adatom diffusion lengths for higher crystal quality achieved by long surface diffusion lengths, MME can reduce Al-vacancy concentrations known to pair with silicon and oxygen to form deep centers and rob AlN of electrons via DX center formation.

In addition, DX center formation requires geometric rearrangements of the dopants. As the lattice expands at the extremely higher temperatures (1100-2200° C. for many growth methods compared to 600-700° C. disclosed herein) the 5.27×10⁻⁶ thermal expansion coefficient predicts an ˜2-6% differential increase in c-axis elongation enhancing the likelihood of atomic rearrangements resulting specifically from the c-axis bond breakage, a requirement for DX center formation. In short, while low temperature growth of AlN and AlN based semiconductors is counter intuitive to most Nitride semiconductor growers, a deep analysis of the mechanisms controlling dopant placement and activation shows that MME provides a high purity, low outgassing environment absent of Al vacancies with long add atom diffusion lengths and a denser crystal less prone to crystalline rearrangement.

The atomic radii matching of Si and Al in AlN, and the optimal MME growth kinetics make a strong case to investigate n-type Si doped AlN films. N-type AlN in combination with the previously achieved p-type AlN:Be MME films completes the essential components to demonstrate AlN diodes and a wide variety of electrical and optical devices constructed from these p and n-type basic building blocks.

### Example 3—Methods of Making AlN:Si and AlN:be Films

The AlN:Si films and AlN homojunction diodes were grown in a Riber 32 plasma-assisted molecular beam epitaxy (PAMBE) system via MME on HVPE AlN on sapphire templates from MSE Supplies. Two-inch diameter AlN on sapphire wafers obtained from MSES were first piranha (3:1 volume ratio of H₂SO₄:H₂O₂) cleaned for 1 minute at 150° C. followed by 5:1 volume ratio of deionized water to hydrofluoric acid (DI H₂O:HF) for 30 seconds. The cleaned wafers were later backside metalized with 2 μm Tantalum for uniform heating during growth. The backside metalized wafers were later diced into 1 cm×1 cm templates. The metalized and diced AlN templates were subsequently solvent cleaned (acetone clean at 45° C. for 20 minutes, 3 minutes methanol clean, DI water rinse, and blown dry with nitrogen), followed by a 10-minute piranha (3:1 volume ratio of H₂SO₄:H₂O₂) clean at 150° C. to remove organic solvents. The templates were then ex situ chemically cleaned in a 10:1 volume ratio of DI H₂O:HF for 25 seconds to partially remove the surface oxides followed by DI water rinse and dried with nitrogen.

The AlN templates were immediately loaded into an introductory chamber with a base pressure of ˜10⁻⁹ Torr and thermally outgassed at 200° C. for 20 minutes. Later, the templates were moved through an analytical chamber into the growth chamber and outgassed at 850° C. for 30 minutes.

Al, Be and Si fluxes were supplied from standard effusion cells. A Veeco UNI-bulb radio frequency (RF) nitrogen plasma source was used to supply nitrogen plasma during growth at a RF plasma power of 350 W and a flow rate of 2.5 sccm. The RF plasma power and flow rate were kept constant for all the growths. The MBE growth chamber base pressure was ˜5×10⁻¹¹ Torr and the beam equivalent pressure (BEP) of the nitrogen plasma was ˜1.2×10⁻⁵ Torr. The growth rate was 700 nm/hour for the AlN:Be films, and 1.40 pm/hour for the AlN:Si films. However, MME can provide growth rates as high as ˜10 m/hour. The MME open/close shutter cycle scheme for the AlN:Be and AlN:Si samples is given in Table 2 noting that each cycle has a period where all metal is consumed and thus, no growth takes place during these periods.

TABLE 2
Description of the MME p-type AlN:Be and n-type AlN:Si films.

| | MME Shutter Cycle | Growth Time per |
|---|---|---|
| Sample | Open/Closed Times | MME Shutter Cycle |
| ID | (sec/sec) | (sec) |
| AlN:Be | 5/10 | 6.5 |
| AlN:Si | 21/11 | 27.3 |

A STAIB Instruments RH20S 20 kV Reflection High Energy Electron Diffraction (RHEED) gun was used in combination with k-Space Associates kSA 400 analytical RHEED system to monitor in situ surface morphology and to calculate the run-time growth rates of the films. The AlN:Be films were grown at a III/V ratio of 1.3 and at substrate temperature of 700° C. using precisely controlled (by shutter timing) excess metal coverage to compensate for the loss of adatom mobility at low temperatures. Al, N and Be atoms hopping on a metal terminated surface need only to break weak metallic bonds that are substantially smaller than the strong AlN semiconductor bonds of a stoichiometric AlN surface. The no-growth time, dead time, was kept at 8.5 see to consume the excess metal and dopants in each cycle and not let the dopants diffuse vertically during growth. The metal-rich conditions result in smooth surface morphology of the films while the low substrate temperature helps in limiting Be-diffusion in the growth direction allowing placement of dopants precisely where desired inside a device and prevents desorption of Be which could result in reactor memory effects wherein subsequently grown films are doped unintentionally with Be. The AlN:Si films were grown under high crystalline MME growth conditions (higher III/V ratios and metal dose—see table 2 and prior description) not suitable for proper p-type doping at a substrate temperature of 800° C. and at a III/V ratio of 1.3.

### Example 4—Charge Carrier Concentration Measurements of AlN:Si and AlN:be Films

Pt/Pd/Au (10 nm/10 nm/100 nm) contact stacks were deposited in a Denton Explorer e-beam evaporation chamber for both n- and p-type AlN films, for Hall measurements (in the van der Pauw configuration) and for device characterization. The contacts were subsequently annealed under purified nitrogen inside a MILA-3000 rapid thermal annealing (RTA) furnace at 800° C. for one minute p-type AlN films, and at 875° C. for one minute for n-type AlN:Si films. Secondary Ion Mass Spectroscopy (SIMS) of a Si doped calibration sample was performed at Evans Analytical Group (EAG). A state-of-the-art Hall measurement tool, M91 FastHall Controller from Lake Shore Cryotronics Inc., was used for four-point resistivity and Hall effect measurements. The FastHall station has a 1T magnet resistance measurement range of 1 mΩ-1 GΩ and mobilities measurement range of 10⁻²-10⁶ cm²/Vs.

The Si incorporation into AlN was calibrated via SIMS. 150 nm thick MME AlN:Si layers of various Si doping were grown at a growth temperature of 800° C., III/V ratio of 1.3 and MME O/C shutter cycles of 21 s open and 11 s closed. SIMS results were then used to guide the doping of thicker films used for Hall analysis. Specifically, 500 nm AlN:Si films were grown via MME on MSES HVPE AlN on sapphire templates at a substrate temperature of 800° C., III/V ratio of 1.3 and MME O/C shutter cycles of 21 s open and 11 s closed with Si SIMS determined concentrations in the range of 5×10¹⁷ to 7×10¹⁹ cm⁻³ as summarized in Table 3.

A metal stack of 10 nm Pt/10 nm Pd/100 nm Au was chosen as contacts to the AlN:Si films for Hall and resistivity measurements. The contacts were deposited at the corners of very large 1×1 cm² samples via lithography and lift-off. First, the samples were cleaned via acetone, isopropanol (IPA), DI water, and dried with nitrogen followed by dehydration bake at 100° C. for 5 minutes. Subsequently, NR9-1500PY negative photoresist (PR) was spin coated at 3000 rpm for a dwell time of 40 sec and at a ramp rate of 5 sec followed by a pre-exposure bake at 150° C. for 60 sec. The PR spin-coated and baked samples were then exposed under 365 nm ultraviolet light at a dose of 350 mJ/cm² followed by a post-exposure bake at 100° C. for 60 sec. The PR spin coated and exposed samples were then developed in RD6 for 10 sec followed by a 1:1 ratio of buffered oxide etch (BOE):DI water clean for 30 sec. The 10 nm/10 nm/100 nm Pt/Pd/Au contacts were deposited inside a Denton Explorer e-beam evaporator at a deposition rate of 0.1 nm/see a background pressure of ˜1×10⁻⁶ Torr followed by a lift-off in acetone for 20 minutes. The samples were finally rinsed via IPA and DI water and dried with nitrogen. The lithography and lift-off process resulted in van der Pauw configuration for contact current-voltage linearity checks and Hall measurements.

After deposition of the contacts, the samples were then annealed in a MILA-3000 rapid thermal annealing (RTA) furnace. The annealing time was 1 minute with a ramp-up and ramp-down time of 60 sec each at 875° C. under nitrogen environment.

A separate p-type sample, N4492, doped at 7×10¹⁸ cm⁻³ Be grown at a substrate temperature of 700° C. and MME Open/Closed cycle of 5 s/10 s was used for circular transmission line measurements (CTLM) for contact resistance comparison of individual films vs device contacts.

Certain n-type AlN sample films and/or devices and some key parameters are provided in Table 3. For an example PIN diode N4633, first a 1 m n-type AlN:Si film with Si doping of 8×10¹⁸ cm⁻³ was grown at a substrate temperature of 800° C. and MME Open/Closed cycle of 21 s/11 s, and III/V ratio of ˜1.8 on a ˜4 m HVPE AlN on a sapphire template from MSES Inc. Then a 200 nm AlN:Si film with Si doping of 5×10¹⁷ cm⁻³ “i-layer” corresponding to an unmeasurably low doping as shown in Table 3 was grown under the same conditions. This was followed by a 200 nm AlN:Be p-type film with Be doping of 7×10¹⁸ cm⁻³ grown at a substrate temperature of 700° C. and MME Open/Closed cycle of 5 s open and 10 s closed with a III/V ratio of ˜1.3.

TABLE 3
Description of MME grown AlN:Si films with their SIMS concentration,
Hall concentration, hall mobility, and growth temperature.

| | SIMS | Hall | Hall | Growth |
|---|---|---|---|---|
| Sample | Concentration | Concentration | Mobility | Temperature |
| ID | (cm⁻³) | (cm⁻³) | (cm²/V-sec) | (° C.) |
| N4591 | 5 × 10¹⁷ | Not | Not | 800 |
| | | measurable | measurable | |
| N4592 | 3 × 10¹⁸ | 9 × 10¹⁷ ± 1 × 10¹⁵ | 63 | 800 |
| N4595 | 8 × 10¹⁸ | 5 × 10¹⁷ ± 1 × 10¹⁵ | 370 | 800 |
| N4596 | 3 × 10¹⁹ | 1 × 10¹⁸ ± 5 × 10¹⁵ | 273 | 800 |
| N4597 | 7 × 10¹⁹ | 6 × 10¹⁸ ± 5 × 10¹⁵ | 17 | 800 |

After growth, 100 m diameter quasi-vertical devices were fabricated on the sample using ICP plasma etching. The same metal stacks used for the individual layers above were used for the p and n-type contacts except they were annealed at 950° C. under nitrogen environment for 1 min. The higher annealing temperature was determined by iterative cycles of anneals at lower temperature, current measurement and subsequent higher temperature anneals until the performance degraded. The higher rapid thermal annealing temperature for these devices seems to be related to the different metal coverage of the device mask compared to the contact study mask and likely is a result of AlN's transparency in the optical heated annealer.

Size (strain) dictates that Si is the best donor dopant atom substituting the Al atom in AlN. The atomic radius of Si (111 pm) closely matches with the atomic radius of Al (118 pm). The atomic radius matching of Si with Al in AlN in combination with the capability of MME to surpass the solubility limit of dopants in III-nitride materials via improved growth kinetics (non-equilibrium growth via rapid synthesis) was utilized to investigate Si doped AlN films. First, the Si incorporation into AlN was calibrated via secondary ion mass spectroscopy (SIMS). Multiple 150 nm thick MME AlN:Si layers of various Si doping were grown and SIMS results were then used to guide the doping of thicker films used for Hall analysis. Specifically, 500 nm AlN:Si films were grown with Si SIMS determined concentrations in the range of 5×10¹⁷ to 7×10¹⁹ cm⁻³ as summarized in Table 3.

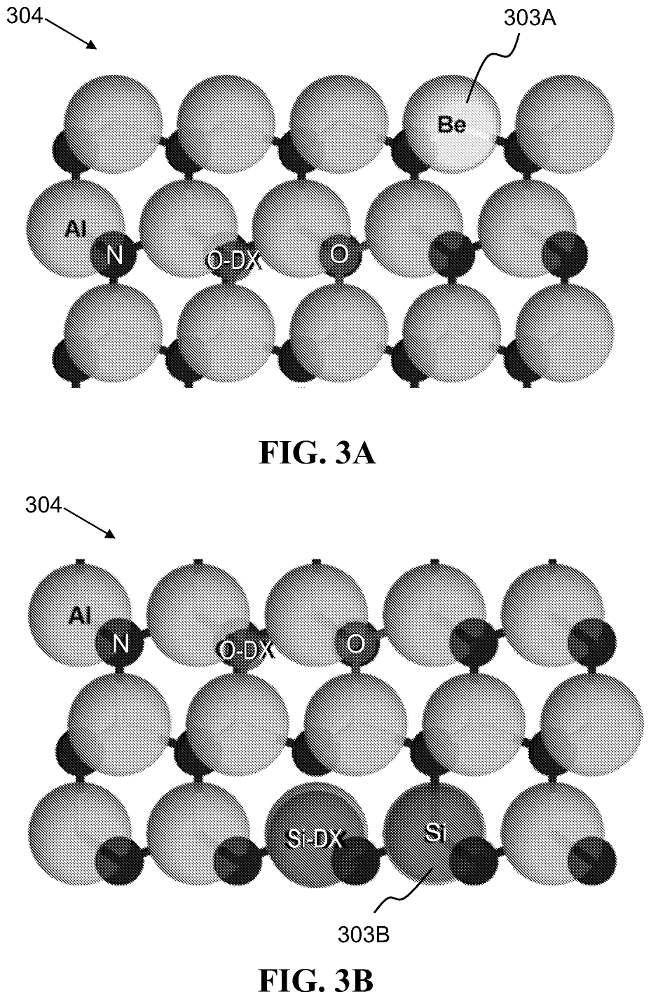

A metal stack of Pt/Pd/Au was deposited via lithography at the corners of very large 1×1 cm² AlN:Si samples in a van der Pauw configuration for contact current-voltage linearity checks and Hall measurements. The use of large samples ensures that the measured properties are global properties and not merely local anomalies. After deposition of the contacts, the samples were then annealed via a rapid thermal annealing (RTA) furnace. The effect of the annealing process on the electrical contact properties of the samples was studied by investigating its I-V characteristics through a four-point probe measurement. I-V characteristics for the Pt/Pd/Au contacts on a representative MME grown films are shown in FIGS. 4A and 4B. The annealed N4595 AlN:Si film in FIG. 4A critically crosses zero current at zero voltage indicating that thermal voltages or piezoelectric offsets are not present. Also, the post-annealed AlN:Si contacts are highly linear. The post-annealed AlN:Si film (N4595) shown in FIG. 4A has ˜5 orders of magnitude higher current than a control undoped AlN film (N4436) shown in FIG. 4B which proves the increased conductivity was a result of the Si doping.

The conductivity of the AlN:Si samples was investigated through Hall measurements. The contact resistance of the AlN:Si films were in the kΩ range which is well within the measurement capability of the Lake Shore Hall tool. However, Hall measurements of the lowest doped AlN film, N4591, could not be performed due to a National Institute of Standards and Technology (NIST) “F-factor” symmetry coefficient of less than 95% in the various measured contact resistances. Hall measurements of the AlN:Si films in the Si doping range of 5×10¹⁷ to 7×10¹⁹ cm⁻³ show reliable results, F>99% with electron concentrations in the range of 9×10¹⁷ to 6×10¹⁸ cm⁻³ as listed in Table 3. The 6×10¹⁸ cm⁻³ electron bulk concentration in AlN is ˜6000 times higher than the previously reported prior art.

Given the contacts' resistance is still high compared to the film resistance, a contact voltage drop added to the bulk resistivity voltage drop in the van der Pauw measurement making the resistivity (and the corresponding mobility) measurements uncertain. Thus, only estimates of the electron mobilities are provided. The current and voltage are measured from different contacts for the carrier concentration determination in Hall measurements and therefor, this contact voltage drop effect did not degrade the carrier concentration determination and all reported carrier concentrations have an uncertainty of less than 0.5%.

### Example 5—Transmission Line Measurements of AlN:Si and AlN:be Films

Transmission line measurement is a technique used to determine the contact resistance between a metal and a semiconductor but also is used to determine the linearity (relative Ohmic versus Schottky rectifying nature) of a contact. The technique involves making a series of metal-semiconductor contacts separated by various distances, or gaps. Resistance between the pair of contacts is measured by applying a voltage across the contacts and measuring the resulting current. The current flows from the first probe, into the metal contact, across the metal-semiconductor junction, through the sheet of semiconductor, across the metal-semiconductor junction again (except this time in the other direction), into the second contact, and from there into the second probe and into the external circuit to be measured by an ammeter. The resistance measured is a linear combination (sum) of the contact resistance of the first contact, the contact resistance of the second contact, and the sheet resistance of the semiconductor in-between the contacts.

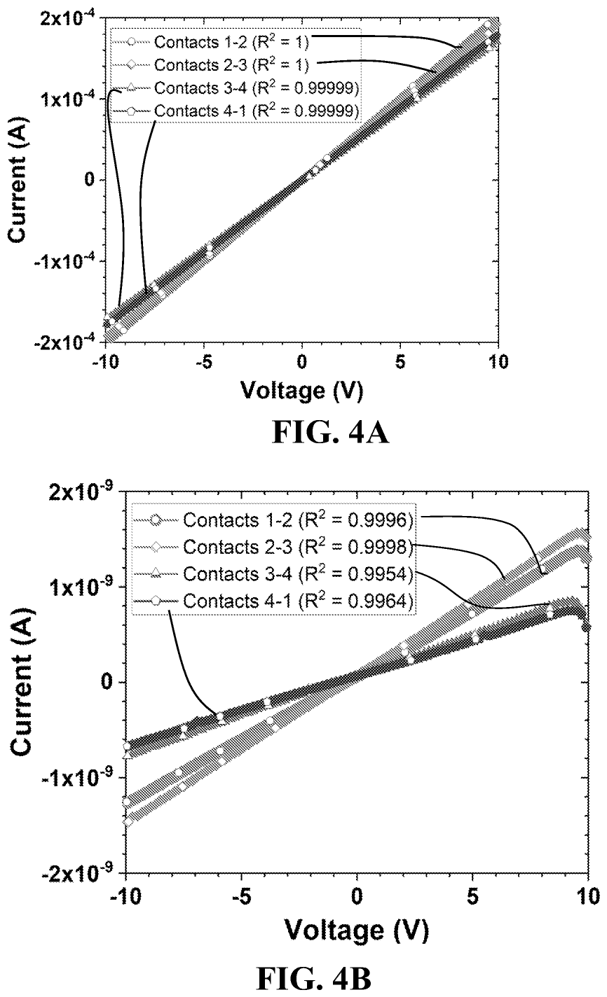

FIG. 5 shows p-contacts transmission line measurement (PTLM) for N4492, a planar p-type film with a constant outer radius of 200 m and gaps of 25, 35, 45, 55, 65, and 75 m. In N4492, the gaps are much smaller than used for the Hall measurements (˜1 cm) of the p-type AlN:Be film, and thus, the current levels of the present method and device are significantly higher. The contacts of p-type film N4492 are highly linear carrying a significant current of ˜0.4 mA.

Certain p-type AlN sample films and/or devices and some key parameters are provided in Table 4. For validation of the p-type nature of the AlN:Be films and the n-type nature of the AlN:Si films, an AlN homojunction diode showing a turn on voltage comparable to the semiconductor bandgap is desired. In this regard, an AlN PIN diode (N4633) was grown. Those in the art will realize that given the n and p-type layers were the impediment prior to this invention, the i-layer can be replaced with quantum wells, or various other modifications to implement diodes appropriate for spontaneous or stimulated light emission, light detection and electrical rectification and carrier modulation as in a transistor.

TABLE 4
Description of MME grown AlN:Be films with their SIMS, Hall concentration,
hot probe magnitude and polarity, and growth temperature.

| | SIMS | Hall | Hot Probe | | Growth |
|---|---|---|---|---|---|
| Sample | Concentration | Concentration | Magnitude | | Temperature |
| ID | (cm⁻³) | (cm⁻³) | and Polarity | | (° C.) |
| N4436 | Not measured - | Not | Not | | 600 |
| | Undoped | measurable | measurable | | |
| N4481 | 2 × 10¹⁶ | p = 3.4 × 10¹² | −90 | mV p-type | 600 |
| N4487 | 5 × 10¹⁶ | p = 2.3 × 10¹⁵ | −100 | mV p-type | 600 |
| N4434 | 2.2 × 10¹⁷ | p = 4.7 × 10¹⁶ | −25 | mV p-type | 600 |
| N4472 | 2 × 10¹⁸ | p = 2.0 × 10¹⁶ | −80 | mV p-type | 600 |
| N4435 | 7 × 10¹⁸ | p = 1.4 × 10¹⁷ | −30 | mV p-type | 600 |
| N4484 | 7 × 10¹⁸ | p = 2.2 × 10¹⁷ | −160 | mV p-type | 600 |
| N4480 | 7 × 10¹⁸ | p = 7.6 × 10¹⁷ | −140 | mV p-type | 600 |
| N4476 | 2 × 10²⁰ | p = 3.6 × 10¹⁶ | −240 | mV p-type | 600 |
| N4492 | 7 × 10¹⁸ | p = 1.1 × 10¹⁸ | −90 | mV p-type | 700 |
| N4491 | 4 × 10¹⁹ | p = 3.1 × 10¹⁸ | −160 | mV p-type | 700 |
| N4490 | 2 × 10²⁰ | p = 8.1 × 10¹⁷ | −200 | mV p-type | 700 |

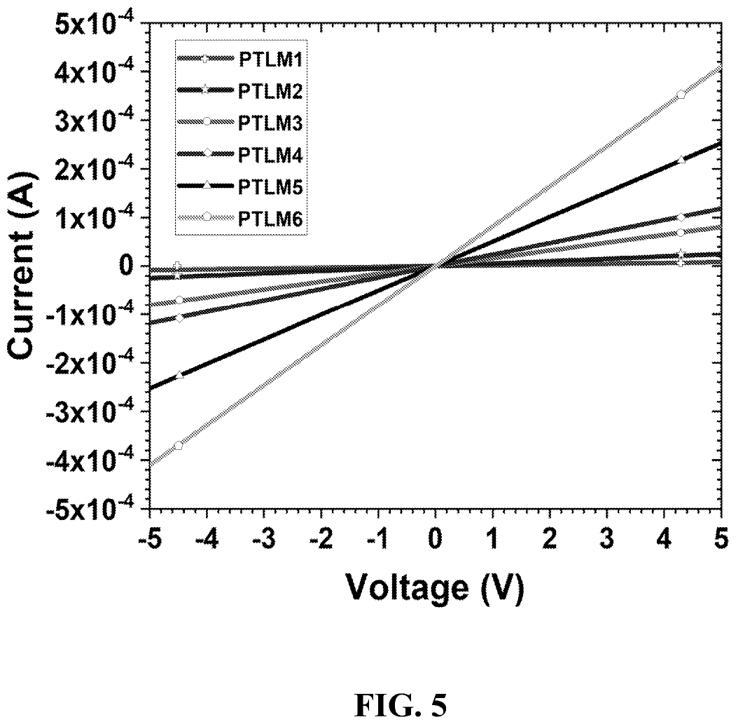

FIGS. 6A and 6B show circular transmission line measurements (CTLM) for n-type and p-type contact layers of the PIN diode structure. Both n-type and p-type contacts all show a linear trend. However, the current levels of both the n-type and p-type contacts for the N4633 AlN diode are repeatably lower for multiple fabricated devices than the n-type N4595 and p-type N4492 films (non-device) presumably due to an anomaly from the plasma tool and annealing during the fabrication process. Specifically, when the PIN diode was etched a dark tint formed in the wafer from an unknown origin, suggesting that the plasma etching of Be and Si doped AlN needs further optimization. This color change (presumed to be contamination) could not be removed and could introduce a combined increase in the contact resistance of the homojunction AlN diode by 3-4 orders of magnitude for two contacts. The current of the n-type layer of the device N4633 (etched) was ˜2-3 orders of magnitude lower than the n-type film N4595 (unetched) for the same contact patterns. Also, the current of the p-type layer on the device N4633 (processed but not etched) was lower by ˜<1 order of magnitude as compared to the p-type film N4492 (unprocessed). This reduction in current through the p-type contacts of the device N4633 is attributed to higher annealing temperature than optimal for the p-type contact layer necessary to optimize the worse conducting n-type contact. Future studies will use individual anneals for n and then p-type contacts but were not pursued here in this initial study due to the complexity of optimal temperatures found based on mask metal coverage (see methods section).

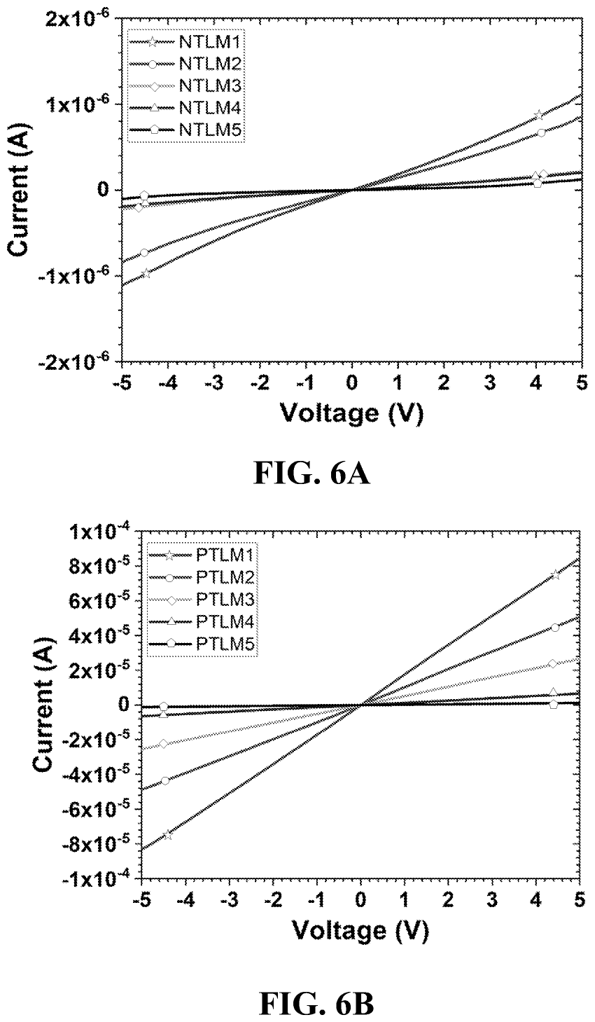

Nevertheless, the forward diode response was nearly ideal except for the high series resistance owing to the aforementioned contact issues with the fabricated device. FIGS. 7A and 7B show the linear and semilog current density-voltage (JV) characteristics of the N4633 AlN PIN diode. The turn on voltage in the linear and semilog plots is ˜6 V, which is in line with expectations for a 6.1 eV AlN semiconductor. While a clear 6 orders of magnitude of rectification is shown, a low breakdown voltage and very high series resistance is also evident by the high current density tail on the semilog plot and the soft turn on in the linear plot. The current density of this sample can be further improved by 3-4 orders of magnitude by optimizing the fabrication process of the device to match that of the previously processed films. Still, the small reverse to large forward current sweep shows 6 orders of magnitude rectification in this first-ever AlN homojunction diode which may be further improved for achieving even higher performance high-power and high-energy devices by optimizing the growth and fabrication conditions.

### Example 6—SIMS Concentration Compared to Depth of AlN:be Films

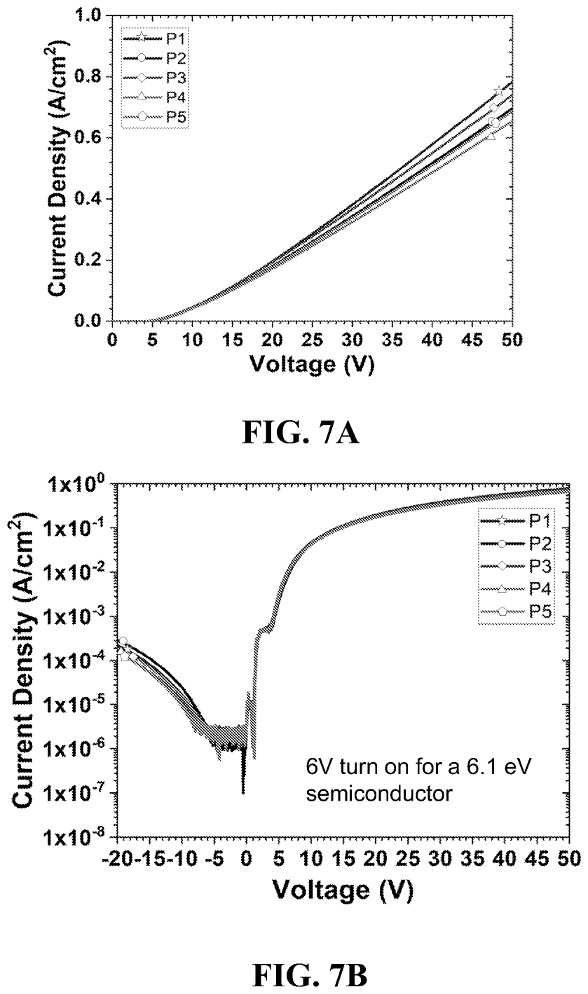

FIG. 8A shows Be SIMS concentration plotted vs sample depth. Abrupt Be profiles were observed in the AlN films. Be is a small atom known to diffuse from the location where it was placed during epitaxy, often smearing out doping profiles. However, as disclosed herein, the low substrate temperatures of the present invention allow accurate and permanent placement of the Be dopants making device Be dopant profiling in III-Nitride semiconductors practical for the first time. FIG. 8B shows a straight-line Be doping profile on a logarithmic scale indicating exponential dependence of the Be doping on its cell temperature indicating that the effusion cell is still in its Knudsen limit, i.e providing a linear relationship between evaporated Be flux and incorporated Be dopant.

### Example 7—Example Devices with Highly Doped AlN:be and AlN:Si Layers

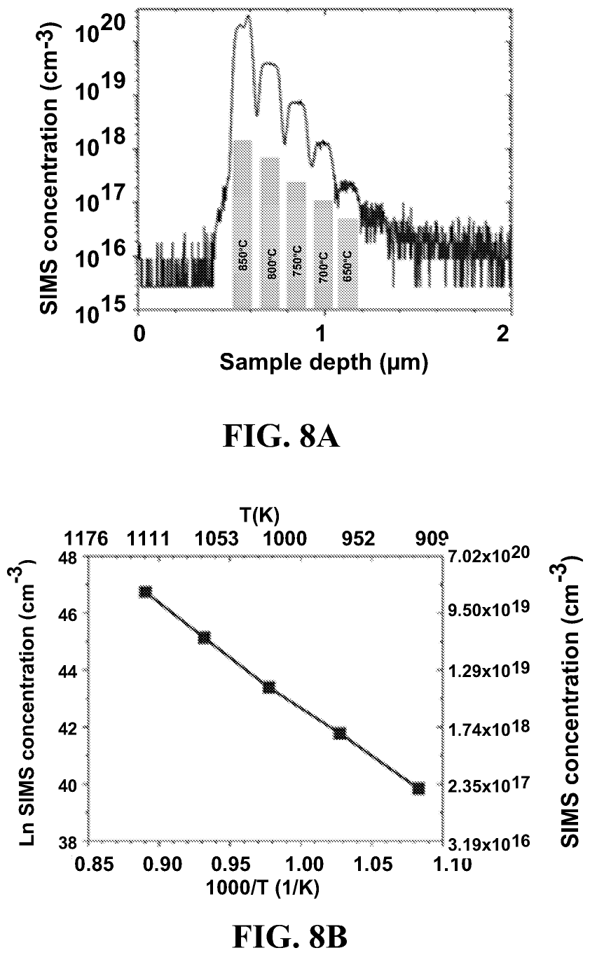

In some examples, AlN films of varying dopants can be grown in layers using the methods disclosed herein. FIG. 9 shows a layer schematic diagram and the corresponding representative RHEED patterns of these films confirming crystalline material even at these excessively low growth temperatures. After cleaning and outgassing of the MSES HVPE AlN template, first an undoped 300 nm AlN buffer layer was grown at a substrate temperature of 800° C. atop the HVPE AlN template so as to bury surface contaminants, such as oxygen which is a strong compensating defect for Be. Al is well known to getter oxygen and there would presumably be diffusion of oxygen up to a few hundred nanometers into the regrown AlN film. The buffer layer was intended to limit high concentrations of oxygen that could otherwise compensate the AlN:Be film. The top 100 nm AlN:Be was grown at the optimized p-type MME growth conditions usually grown for GaN. The lower substrate and longer shutter closed times limited the vertical surface diffusion of Be in the growth direction while the metal rich III/V ratio of 1.3 enables smooth surface morphology that targets a slightly spotty RHEED indicative of a slightly faceted surface. The top layer was doped with Be. The progression of the RHEED images with time and the post growth Atomic Force Microscopy (AFM) suggest that the MME grown AlN does develop a slightly rougher (˜2-3 nm root mean square (RMS) roughness films versus ˜1.9 nm RMS roughness for the template) morphology common for all p-type III-Nitrides by all growth methods as well as surface pitting common to MBE grown in the intermediate phase regime, as the film thickens. Furthermore, the highest doped film has additional surface features that may be segregated Be owing to the concentration being substantially greater than the solubility limit. Interestingly, the pit density is remarkably higher in the undoped film and reduces with increasing Be concentration suggesting the Be may have some beneficial surfactant effect. Next, contacts were deposited via electron beam evaporation on these films. Those in the art will realize that devices can contain various discrete and continuous variable doping concentrations useful for controlling electrical and optical characteristics.

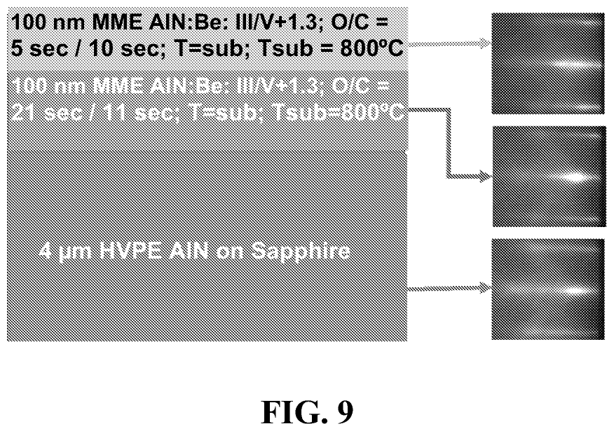

Hall measurements of the AlN:Be samples were performed by the M91 FastHall Controller from Lake Shore Cryotronics. The system is capable of measuring sample resistances up to 1 GQ. The contact resistance of the AlN:Be films were in the megaohm range which is well within the measurement capability of the Lake Shore Hall tool. However, Hall measurements of the undoped AlN film N4436 could not be performed due to their very high contact resistances. Hall measurements of the AlN:Be films grown at 600 and 700° C. substrate temperatures are listed in Table 4. These measurements were in a reliable range with symmetry factors 96-99.9% and Hall voltage signal-to-noise ratios of 100-900 for all measurements. Confirmation of the conductivity type was also achieved via hot probe measurements. The hot probe measurements of the unintentionally doped sample N4436 was unmeasurable (the voltage drifted as when a voltage probe floats on an insulator). The AlN:Be films grown at 600° C. in Table 4 in the Be doping range of 5×10¹⁶-7×10¹⁸ cm⁻³ show reliable results with hole concentrations in the range of 2.3×10¹⁵-7.6×10¹⁷ cm⁻³. These results are plotted in FIG. 10. The activation efficiency of Be extracted from this figure is found at ≈5% in MME AlN:Be films grown at 600° C.

### Example 8—Activation Energy Measurement of Highly Doped AlN:be and AlN:Si Devices

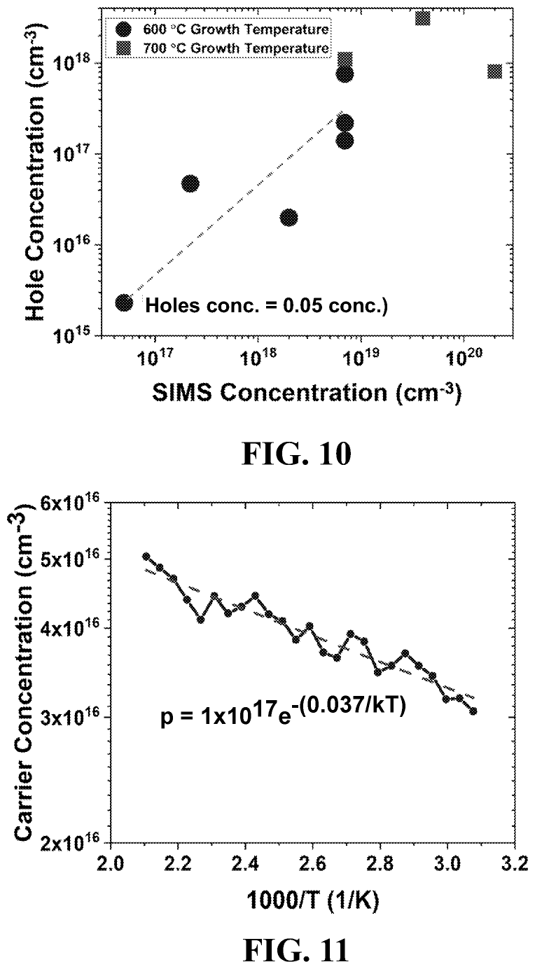

Independent confirmation of the conductivity type and experimental activation energy measurement for the N4472 AlN:Be sample was performed at Lake Shore Cryotronics. This sample was selected because relative to a lower doped sample, N4434, it showed a lower hole concentration suggesting a significant degree of compensation. High temperature DC and FastHall Hall measurements of this sample were performed in the temperature range of 325-475 K and shown in FIG. 11. All the measurements showed p-type conductivity with the fit resulting in a curve p=1×10¹⁷e^{-(0.037/kT)}. For this sample, the compensation appears to be ≈95% since the SIMS concentration is 2×10¹⁸ cm³. This provides insight into the likely source of run-to-run variability as shown in FIG. 10 where several different hole concentrations are measured for approximately the same doping. Beyond self-compensation from Be placed on interstitial sites, compensation either by defect trapping due to the low growth temperatures used or impurities like oxygen may play a significant role in the hole concentrations obtained.

### Example 9—Growth Kinetics of AlN:be Films

Growth kinetics of AlN:Be films were measured by growing films in the range of Be dopant concentrations of 0 (Sample number=N4436), 2×10¹⁷ (N4434), 7×10¹⁸ (N4435), and 1×10²⁰ cm⁻³ (N4433), as set forth in Table 5. The films were grown on MSES HVPE AlN templates. Pt/Pd/Au (10 nm/10 nm/100 nm) Van der Pauw contacts were deposited via e-beam evaporation. Before annealing all the samples showed non-ohmic behavior with current at +/−10 Volts at the noise floor of the latest Hall Effect Measurement (HEM) equipment in the market, a Lake Shore Fasthall M91 system. The samples were then annealed at 700° C. for 10 minutes under nitrogen at a flow rate of 400 sccm. After annealing, N4433 and N4436 still showed non-ohmic behavior and small currents. However, N4434 and N4435 exhibited extremely ohmic behavior with currents 4-5 decades higher than prior to annealing.

TABLE 5
Description of MME grown AlN:Be films
with varying Be dopant concentrations

| Sample ID | Be Dopant Concentration (cm⁻³) |
|---|---|
| N4436 | 0 |
| N4434 | 2 × 10¹⁷ |
| N4435 | 7 × 10¹⁸ |
| N4433 | 1 × 10²⁰ |

Hot probe measurements of the samples performed via a high impedance Keithley 6517A electrometer showed n-type behavior for N4433 and N4436 while p-type behavior was observed for N4434 and N4435. Four-point resistivity and Hall measurements of N4433 and N4436 could not be performed due to contacts' failure. 100 repeated measurements were taken for both resistivity and Hall measurement of both N4434 and N4435 for increased reliability and statistical validation of the results. Longer measurement times of several hours were employed to cater for RC time constants of the contacts.

Validating the thermal probe results of p-type conduction, Hall measurements showed p-type conductivity for all the 100 repeated measurements of both N4434 and N4435 with hole concentrations of 4.65×10¹⁶ and 1.4×10¹⁷ cm⁻³ respectively. It is noted that since during Hall measurements, the current flows through different contacts than the Hall voltage is measured, and since contacts were absent of rectification and symmetric in repeated trials with reversed polarities per NIST standards, the Hall results are accurate to +/−2×10¹⁴ and 4×10¹⁴ cm⁻³ respectively. Four-point resistivity of N4434 and N4435 showed resistivity values of 12.2 and 6.5 mΩ-cm, respectively but could be underestimates of the actual values since N4434 and N4435 exhibited linear but very high contact resistances of ˜15 and 6 MΩ, respectively. Hall voltage levels of the measurements were verified with Lake Shore staff, and it was found that the Hall voltage levels in the measurements were way above the noise levels with a signal to noise level of 203 and 316 respectively.

Purlieu (full-width at fractional peak heights to delineate the thin film from the bulk material) symmetric and asymmetric XRD rocking curves showed the regrown films closely matched the crystalline quality of the underlying templates. Furthermore, it was found that the (002) symmetric quality of AlN decrease only slightly with Be concentration, however, both (105) and (102) asymmetric quality improves slightly with Be concentration suggesting a modest change in defect structure yet to be explored.

### Example 10—Metallic Cleaning to Reduce Defect Density

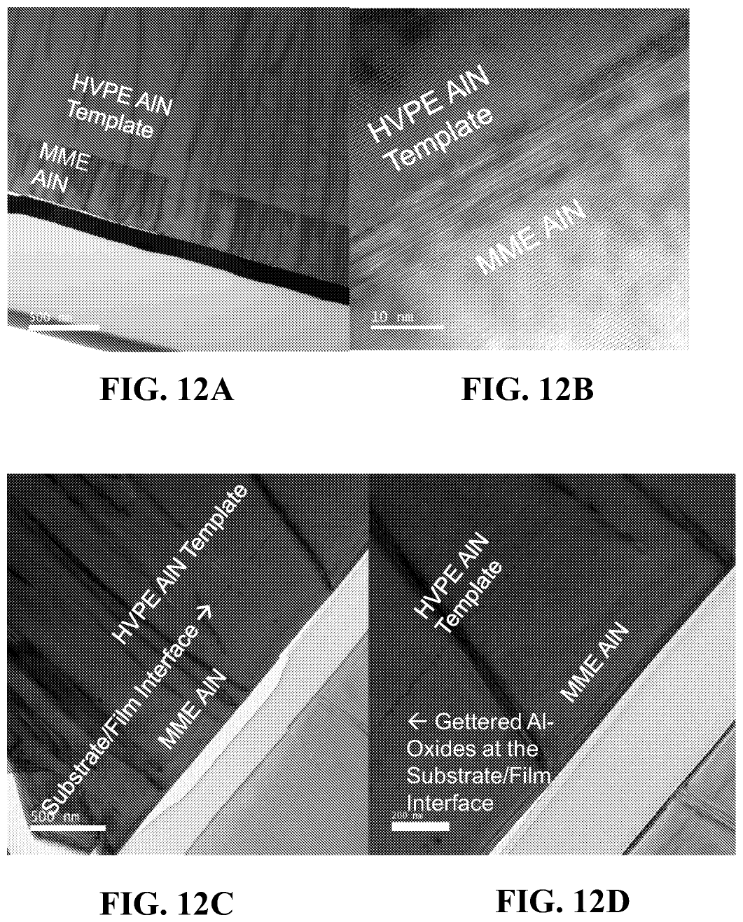

FIGS. 12A-12F show cross-sectional transmission electron microscope slides showing extra (more than already exist in the substrate) defects that form when the substrates do not undergo a procedure called “Al flashing.” Al flashing involves flooding the surface with Al metal that helps remove stubborn surface oxides and allows the substrate crystal to be replicated without added defects. As shown, using Al flashing, the stacking faults and edge dislocations are substantially reduced or eliminated. In addition, no increase in screw dislocations occurs. FIGS. 12A and 12C highlight all defects (edge, screw and stacking faults) in a MME-grown AlN, whereas FIGS. 12B and 12D illustrate metallic aluminum cleaning that drastically reduces defect density.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

1. A method of forming a device comprising:
disposing, over a substrate at a temperature below about 1000° C., a doped material comprising:
a group III metal nitride; and
at least one of a p-type dopant or an n-type dopant;
wherein the doped material has a bandgap energy greater than 4.5 electronvolts (eV).

2. The method of claim 1, wherein the doped material at least one of:
comprises the dopant in a concentration ranging from about 1×10¹¹ cm⁻³ to about 3×10²⁰ cm⁻³;
has a hole-carrier concentration of at least about 1×10¹¹ cm⁻³;
has an electron-carrier concentration of at least about 6×10¹⁵ cm⁻³; or
achieves at least 100 thousand increased electron-carrier concentration compared to a second doped material disposed over a second substrate at a temperature greater than 1000° C.

3-7. (canceled)

8. The method of claim 1, wherein the doped material is configured to emit one or more photons at wavelengths from about 200 nm to about 350 nm.

9. The method of claim 1, wherein the group III metal nitride comprises a material selected from aluminum nitride (AlN), gallium nitride (GaN), aluminum gallium nitride (AlGaN), indium aluminum nitride (InAlN), aluminum scandium nitride (AlScN), indium gallium aluminum scandium nitride (InGaAlScN), or combinations thereof.

10. The method of claim 9, wherein the p-type dopant comprises beryllium (Be).

11. (canceled)

12. The method of claim 1 further comprising disposing a semiconductor upon the doped material.

13. The method of claim 12, wherein the doped material disposed upon the semiconductor forms a homojunction or a heterojunction.

14. (canceled)

15. The method of claim 1, wherein the device is configured to at least one of:
disrupt viral and bacterial replication; or
enhance polymer curing.

16. (canceled)

17. The method of claim 1, wherein the substrate is selected from the group consisting of sapphire, crystalline-silicon, gallium nitride, gallium oxide, aluminum nitride, aluminum gallium nitride, zinc oxide, lithium gallate, lithium aluminate, single crystal diamond, heteroepitaxial single crystal diamond, silicon carbide, and combinations thereof.

18. The method of claim 1 further comprising:
flowing a plasma comprising nitrogen from a remote plasma chamber into a growth chamber; and
introducing a group III metal and the at least one of a p-type dopant or an n-type dopant into the growth chamber.

19.-22. (canceled)

23. The method of claim 18, wherein introducing the at least one of p-type dopant or the n-type dopant into the growth chamber further comprises pulsing one or more fluxes of each respective dopant.

24. The method of claim 23, wherein introducing the at least one of p-type dopant or the n-type dopant into the growth chamber further comprises pulsing one or more fluxes of the group III metal with a constant nitrogen supply.

25. The method of claim 23, wherein each pulse of the pulsing occurs over a delivery period ranging from about 0.1 seconds to about 30 seconds.

26. The method of claim 25, wherein each pulse of the pulsing is separated over a paused period ranging from about 1 second to about 30 seconds.

27. The method of claim 23, wherein each pulse of the pulsing:
occurs over a delivery period ranging from about 1 seconds to about 25 seconds; and
is separated over a paused time period ranging from about 2 seconds to about 15 seconds.

28. The method of claim 1, wherein the temperature at which the doped material is disposed over the substrate is within a range from about 600° C. to about 900° C.

29. The method of claim 18, wherein a III/V flux ratio is greater than about 1.

30. The method of claim 29, wherein the III/V flux ratio ranges from about 1.1 to 1.5.

31. The method of claim 18, wherein if introducing the p-type dopant into the growth chamber, the temperature of the growth chamber is in a range from about 500° C. to about 850° C.

32. The method of claim 1, wherein if introducing the p-type dopant into the growth chamber, the temperature of the growth chamber is in a range from about 600° C. to about 700° C.

33. (canceled)

34. The method of claim 29, wherein the III/V flux ratio ranges from about 1.6 to 2.0.

35. The method of claim 18, wherein if introducing the n-type dopant into the growth chamber, the temperature of the growth chamber is in a range from about 500° C. to about 1000° C.

36. The method of claim 18, wherein if introducing the n-type dopant into the growth chamber, the temperature of the growth chamber is in a range from about 600° C. to about 800° C.

37. The method of claim 1, wherein the device is selected from the group consisting of a diode and a transistor.

38. The method of claim 1, wherein the device is a diode configured to achieve a turn-on voltage of approximately 6 volts (V).

39. The method of claim 1, wherein the device is a heteroepitaxial diode with Schottky, pin and Junction Barrier Schottky (JBS) electrical behavior.

40. (canceled)

41. The method of claim 1, wherein the doped material is a first doped group III metal nitride disposed on the substrate;
wherein the method further comprises disposing, over at least a portion of the first doped group III metal nitride at a temperature below about 1000° C., a second doped group III metal nitride; and
wherein the first doped group III metal nitride comprises a higher concentration of electrical carriers than the second doped group III metal nitride.

42. The method of claim 41 further comprising disposing a Schottky barrier electrode on at least a portion of the second doped group III nitride.

43. The method of claim 41 further comprising disposing an ohmic electrode on at least a portion of the first doped group III-nitride.

44. The method of claim 41, wherein at least one of:
the first doped group III metal nitride has a first electrical-carrier concentration in a range from about 5×10¹⁷ cm⁻³ to about 3×10²⁰ cm⁻³; or
the second p-doped group III metal nitride has a second electrical-carrier concentration in a range from about 1×10¹⁵ cm⁻³ to about 5×10¹⁹ cm⁻³.

45.-58. (canceled)

59. A method of forming a device comprising:
growing a first doped group III metal nitride at a temperature below 1000° C.;
growing a second doped group III metal nitride at a temperature below 1000° C.;
disposing the first doped group III metal nitride on a substrate; and
disposing the second doped group III metal nitride on at least a portion of the first doped group III metal nitride.

60. The method of claim 59, wherein:
the first doped group III metal nitride is a first n-doped group III metal nitride;
the second doped group III metal nitride is a p-doped group III metal nitride; and
the device is a diode.

61. The method of claim 59 further comprising growing a second n-doped group III metal nitride between the first n-doped group III metal nitride and the p-doped group III metal nitride.

62. The method of claim 59 further comprising at least one of:
disposing a Schottky barrier electrode on at least a portion of the second doped group III nitride; or
disposing an ohmic electrode disposed on at least a portion of the first doped group III-nitride.

63. The method of claim 59, wherein:
the doped group III metal nitrides are grown via metal-modulated epitaxy (MME);
the first doped group III metal nitride is a first n-doped group III metal nitride; and
the second doped group III metal nitride is a p-doped group III metal nitride doped with beryllium.

64. The method of claim 59, wherein:
the first doped group III metal nitride comprises one or more n-doped group III metal nitrides;
the second doped group III metal nitride comprises one or more p-doped group III metal nitrides; and
the doped group III metal nitrides are grown via MME;
at least one of:
at least one of the n-doped group III metal nitrides is an n-type GaN doped with germanium (Ge);
at least one of the p-doped group III metal nitrides is a p-type GaN doped with Be; or
at least one of the p-doped group III metal nitrides is a p-type AlN doped with Be.

65. The method of claim 60, wherein at least one of:
the first n-doped group III metal nitride has an electron-carrier concentration from about 1×10¹⁷ cm⁻³ to about 3 x10²⁰ cm⁻³; or
the p-doped group III metal nitride comprising a hole-carrier concentration from about 1×10¹⁷ cm⁻³ to about 3×10²⁰ cm⁻³.

66. The method of claim 61, wherein at least one of:
the second n-doped group III metal nitride has an electron-carrier concentration lower than the first n-doped group III metal nitride;
the second n-doped group III metal nitride is configured to function as an unintentionally doped layer;
the second n-doped group III metal nitride is configured to have an energy bandgap smaller than an energy bandgap of each of the first n-doped layer and the p-doped layer;
the second n-doped group III metal nitride comprises alternating wells;
the second n-doped group III metal nitride comprises alternating wells, each having an energy bandgap smaller than the energy bandgap of each of the first n-doped layer and the p-doped layer;
the second n-doped group III metal nitride comprises alternating wells and alternating barriers, the barriers interspersed between the wells and having an energy bandgap larger than the energy bandgap of the wells;
the second n-doped group III metal nitride comprises alternating wells and alternating barriers, the barriers interspersed between the wells and having an energy bandgap larger than the energy bandgap of the wells, and equal to or less than the energy bandgap of each of the first n-doped layer and the p-doped layer; or
the device is a diode configured to emit one or more photons having a wavelength from about 200 nm to about 350 nm.
